(19) United States
(12) Patent Application Publication
(10) Pub. No.: US 2014/0124250 A1
(43) Pub. Date: May 8, 2014

(54) WIRING BOARD AND METHOD FOR MANUFACTURING SAME

(71) Applicants: Akito Iwasaki, Mie (JP); Tadashi Nakamura, Mie (JP); Tsuyoshi Himori, Mie (JP); Kazuhiko Himori, Mie (JP)

(72) Inventors: Akito Iwasaki, Mie (JP); Tadashi Nakamura, Mie (JP); Tsuyoshi Himori, Mie (JP); Kazuhiko Himori, Mie (JP)

(73) Assignee: PANASONIC CORPORATION, Osaka (JP)

(21) Appl. No.: 13/988,499

(22) PCT Filed: Dec. 25, 2012
(86) PCT No.: PCT/JP2012/008234

§ 371 Date: May 20, 2013

(30) Foreign Application Priority Data
Dec. 26, 2011 (JP) 2011-283189
Jun. 6, 2012 (JP) 2012-128574
Sep. 25, 2012 (JP) 2012-210809

(51) Int. Cl. H05K 1/11; H05K 3/00

(52) U.S. Cl. CPC H05K 1/115; H05K 3/00
USPC 174/255; 29/850

(57) ABSTRACT

A wiring board includes an electric insulating base material including an incompressible member and a thermosetting member; a first wiring and a second wiring formed with the electric insulating base material interposed therebetween; and a via-hole conductor penetrating the electric insulating base material, and electrically connecting the first wiring and the second wiring to each other. The via-hole conductor includes a resin portion and a metal portion. The metal portion includes a first metal region mainly composed of Cu; a second metal region mainly composed of a Sn—Cu alloy; and a third metal region mainly composed of Bi. The second metal region is larger than the first metal region, and larger than the third metal region.

### TECHNICAL FIELD

The present invention relates to a wiring board including wirings which are formed on both surfaces of an electric insulating base material and coupled to each other by via-hole conductors, and a method for manufacturing the wiring board.

### BACKGROUND ART

A wiring board including wirings which are formed on both sides of an electric insulating base material and coupled to each other by via-hole conductors formed by filling conductive paste into holes formed in the electric insulating base material is known. Furthermore, a via-hole conductor, in which metal particles containing copper (Cu) instead of the conductive paste are filled and the metal particles are fixed together by an intermetallic compound, is known. Specifically, a via-hole conductor is known, in which conductive paste including tin (Sn)-bismuth (Bi) metal particles and copper particles is heated at a predetermined temperature, thereby forming a tin (Sn)-copper (Cu) alloy in the vicinity of the copper particles.

FIG. 14 is a schematic sectional view of a via-hole conductor of a wiring board in accordance with a conventional example. FIGS. 15A and 16A are scanning electron microscope (SEM) photographs of a conventional via-hole conductor. FIG. 15B is a schematic view of FIG. 15A. FIG. 16B is a schematic view of FIG. 16A. FIG. 15A is shown at a magnification of 3000 times, and FIG. 16A is shown at a magnification of 6000 times.

Via-hole conductor 2 is brought into contact with wiring 1 formed on a surface of the wiring board. Via-hole conductor 2 includes metal portion 11 and resin portion 12. Metal portion 11 has first metal region 8 including a plurality of copper (Cu)-containing particles 3, second metal region 9 including a tin (Sn)-copper (Cu) alloy, or the like, and third metal region 10 mainly composed of bismuth (Bi). Note here that prior art literatures related to this invention include, for example, Patent Literature 1.

### CITATION LIST

Patent Literature 1: U.S. Pat. No. 4,713,682

### SUMMARY OF THE INVENTION

A wiring board of the present invention includes an electric insulating base material including an incompressible member and a thermosetting member; a first wiring and a second wiring formed with the electric insulating base material interposed therebetween; and a via-hole conductor that penetrates the electric insulating base material and electrically connects the first wiring and the second wiring. The via-hole conductor includes a resin portion and a metal portion. The metal portion has a first metal region mainly composed of copper (Cu), a second metal region mainly composed of a tin (Sn)-copper (Cu) alloy, and a third metal region mainly composed of bismuth (Bi). The second metal region is larger than the first metal region, and larger than the third metal region.

### BRIEF DESCRIPTION OF THE DRAWINGS

FIG. 1A is a schematic sectional view of a wiring board in accordance with an exemplary embodiment of the present invention.

FIG. 1B is a schematic sectional view of a vicinity of a via-hole conductor in accordance with the exemplary embodiment of the present invention.

FIG. 2A is a sectional view showing a method for manufacturing the wiring board in accordance with the exemplary embodiment of the present invention.

FIG. 2B is a sectional view showing the method for manufacturing the wiring board in accordance with the exemplary embodiment of the present invention.

FIG. 2C is a sectional view showing the method for manufacturing the wiring board in accordance with the exemplary embodiment of the present invention.

FIG. 2D is a sectional view showing the method for manufacturing the wiring board in accordance with the exemplary embodiment of the present invention.

FIG. 3A is a sectional view showing the method for manufacturing the wiring board in accordance with the exemplary embodiment of the present invention.

FIG. 3B is a sectional view showing the method for manufacturing the wiring board in accordance with the exemplary embodiment of the present invention.

FIG. 3C is a sectional view showing the method for manufacturing the wiring board in accordance with the exemplary embodiment of the present invention.

FIG. 4A is a sectional view showing a method for manufacturing a multilayer wiring board in accordance with the exemplary embodiment of the present invention.

FIG. 4B is a sectional view showing the method for manufacturing the multilayer wiring board in accordance with the exemplary embodiment of the present invention.

FIG. 4C is a sectional view showing the method for manufacturing the multilayer wiring board in accordance with the exemplary embodiment of the present invention.

FIG. 5A is a schematic sectional view of the vicinity of the via-hole conductor before via paste is compressed.

FIG. 5B is a schematic sectional view of the vicinity of the via-hole conductor after via paste is compressed.

FIG. 6 is a schematic view showing a state of via paste when a member having compressibility is used.

FIG. 7 is a schematic view showing a state of via paste when an incompressible member is used.

FIG. 8 is a schematic view showing a state of via paste when an incompressible member is used.

FIG. 9A is a schematic view showing a state of via paste before an alloying reaction.

FIG. 9B is a schematic view showing a state of the via-hole conductor after the alloying reaction.

FIG. 10 is a ternary diagram showing a metal composition in the via paste in accordance with the exemplary embodiment of the present invention.

FIG. 11A is a view showing a SEM photograph of the via-hole conductor in accordance with the exemplary embodiment of the present invention.

FIG. 11B is a schematic view of FIG. 11A.

FIG. 12A is a view showing a SEM photograph of the via-hole conductor in accordance with the exemplary embodiment of the present invention.

FIG. 12B is a schematic view of FIG. 12A.

FIG. 13 is a graph showing results of analysis by X-ray diffraction of the via-hole conductor in accordance with the exemplary embodiment of the present invention.

FIG. 14 is a schematic sectional view of a via-hole conductor of a wiring board in a conventional example.

FIG. 15A is a view showing a SEM photograph of the conventional via-hole conductor.

FIG. 15B is a schematic view of FIG. 15A.

FIG. 16A is a view showing a SEM photograph of the conventional via-hole conductor.

FIG. 16B is a schematic view of FIG. 16A.

### DETAILED DESCRIPTION OF THE PREFERRED EMBODIMENTS

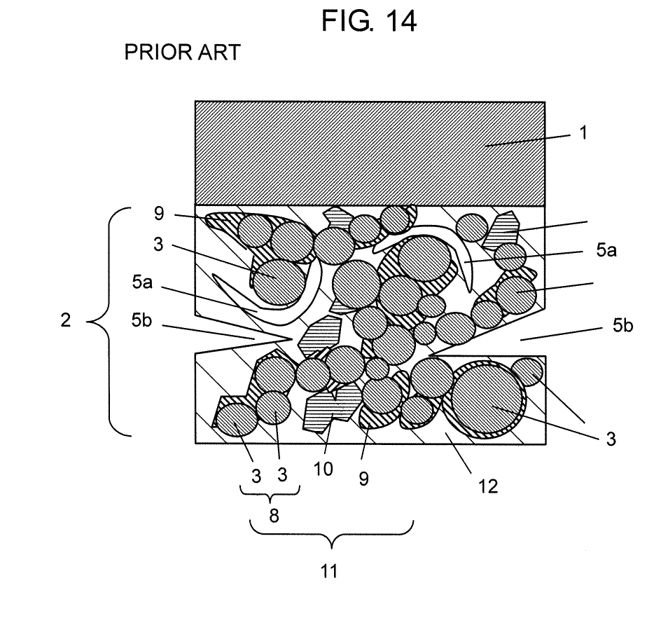

When conventional via-hole conductor 2 undergoes thermal shock in, for example, reflow treatment, Cu diffuses into Sn—Bi metal particles to generate intermetallic compounds such as Cu₃Sn and Cu₆Sn₅. At this time, as shown in FIG. 14, voids 5a or cracks 5b may be generated in via-hole conductor 2. Furthermore, when Cu₆Sn₅ is changed into Cu₃Sn, Kirkendall voids or the like may be generated. Furthermore, with the presence of voids 5a, internal stress may occur in via-hole conductor 2 when Cu₆Sn₅ formed on an interface between Cu and Sn is changed into Cu₃Sn by heating.

Furthermore, in conventional via-hole conductor 2, a volume fraction of resin portion 12 in via-hole conductor 2 is large and a volume fraction of metal portion 11 is small. Therefore, via resistance (a resistance value of entire via-hole conductor 2) may be high.

Hereinafter, a structure of a multilayer wiring board in accordance with the present exemplary embodiment is described.

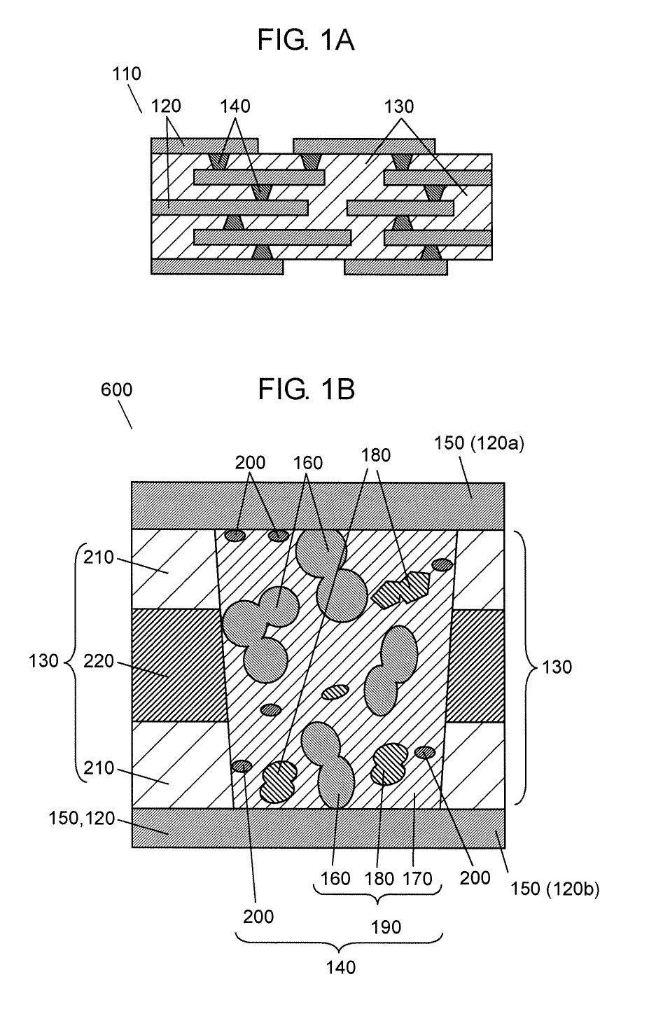

FIG. 1A is a schematic sectional view of the multilayer wiring board in accordance with an exemplary embodiment of the present invention. A plurality of wirings 120 formed inside electric insulating base material 130 are electrically coupled to each other by way of via-hole conductors 140, and thus multilayer wiring board 110 is configured.

FIG. 1B is a schematic sectional view of a vicinity of via-hole conductor 140 in accordance with the exemplary embodiment of the present invention. Multilayer wiring board 110 includes electric insulating base material 130 having incompressible member 220 and thermosetting adhesive layer (thermosetting member) 210, first wiring 120a and second wiring 120b, and via-hole conductor 140. First wiring 120a and second wiring 120b are formed with electric insulating base material 130 interposed therebetween. Via-hole conductor 140 penetrates electric insulating base material 130, and electrically connects first wiring 120a and second wiring 120b together.

Electric insulating base material 130 includes incompressible member 220 such as a heat-resistant film, and thermosetting adhesive layers (thermosetting members) 210 formed on both surfaces of incompressible member 220. First wiring 120a and second wiring 120b formed by patterning metal foil 150 such as copper foil into a predetermined shape are adhesively bonded to incompressible member 220 by way of thermosetting adhesive layer 210. Note here that thermosetting adhesive layer 210 may be formed on only one surface of incompressible member 220.

Via-hole conductor 140 includes metal portion 190 and resin portion 200. Metal portion 190 has first metal region 160 mainly composed of copper, second metal region 170 mainly composed of a tin-copper alloy, and third metal region 180 mainly composed of bismuth. Second metal region 170 is larger than first metal region 160, and larger than third metal region 180.

Resin portion 200 is, for example, epoxy resin. Epoxy resin has excellent reliability. Resin portion 200 is a cured product mainly of resin added into via paste, but a part of thermosetting resin constituting thermosetting adhesive layer 210 may be mixed.

The size (or volume fraction or weight fraction) of second metal region 170 is larger than that of first metal region 160. Furthermore, the size (or volume fraction or weight fraction) of second metal region 170 is larger than that of third metal region 180.

When the size of second metal region 170 is made to be larger than that of first metal region 160 and larger than that of third metal region 180, a plurality of wirings 120 can be electrically coupled to each other mainly by second metal region 170. Furthermore, first metal regions 160 and third metal regions 180 can be scattered (scattered in a state of isolated small islands) in such a manner that they are not brought into contact with each other in second metal region 170.

Furthermore, second metal region 170 includes intermetallic compounds Cu₆Sn₅ and Cu₃Sn, and the ratio of Cu₆Sn₅/Cu₃Sn is 0.001 or more and 0.100 or less. By reducing the amount of Cu₆Sn₅, it is possible to prevent Cu₆Sn₅ remaining in multilayer wiring board 110 from being changed into Cu₃Sn in a heat treatment process such as solder reflow. As a result, generation of Kirkendall voids or the like can be suppressed.

Note here that the ratio of Cu₆Sn₅/Cu₃Sn is desirably 0.100 or less, and more desirably 0.001 or more and 0.100 or less. A reaction time is limited and it is practical that the reaction time is within 10 hours at most. Therefore, it is not likely that the ratio of Cu₆Sn₅/Cu₃Sn is completely 0 within such a limited reaction time. Also, it becomes difficult to quantitatively analyze Cu₆Sn₅ that may remain in only a small amount.

When a usual measuring device is used as mentioned above, it is thought that Cu₆Sn₅ may not be detected (for example, a detected amount becomes 0 in relation to the detection limit of a measuring device). Therefore, when the usual measuring device is used, the ratio of Cu₆Sn₅/Cu₃Sn is 0 or more and 0.100 or less (note here that 0 includes a case where a detected amount is not more than the detection limit that is measurable by the measuring device, or a case where a detection cannot be carried out by a measuring device). Note here that when the measurement accuracy of a measuring device is sufficiently high, the ratio of Cu₆Sn₅/Cu₃Sn may be 0.001 or more and 0.100 or less.

Note here that it is desirable that the ratio of Cu₆Sn₅/Cu₃Sn is 0.001 or more and 0.100 or less as a result of evaluation using an XRD (X-ray diffraction device). However, it is difficult to take out only a minute via portion (or a via paste portion) constituting an actual wiring board, and to analyze the portion by the XRD device. Therefore, a general evaluation device, for example, an elemental analyzer (for example, XMA, EPMA, and the like) using fluorescence X-ray, which is attached to a SEM device, may be used as a measuring device. Furthermore, even if such an elemental analyzer (for example, XMA, EPMA, and the like) is used, the ratio of Cu₆Sn₅/Cu₃Sn is desirably 0.001 or more and 0.100 or less. The XRD carries out a kind of mass spectrometric analysis, and the EPMA carries out a kind of cross-sectional analysis, but there is no substantial difference between them. As mentioned above, in measuring the ratio of Cu₆Sn₅/Cu₃Sn of a minute via portion (or via paste portion), evaluation may be carried out by selecting one of appropriate devices from XRD, XMA, EPMA, or other devices similar to these devices.

Electric insulating base material 130 includes incompressible member 220 such as a heat-resistant film, and thermosetting adhesive layer 210 formed on at least one surface of incompressible member 220.

Note here that it is practical that the definitions of compressibility and incompressibility in the present exemplary embodiment are given based on a configuration of a core material. That is to say, a member has compressibility when it uses, as the core material, woven fabric or non-woven fabric in which a plurality of fibers, regardless of whether the fibers are glass fibers or resin fibers, are entangled with each other. The reason thereof is as follows. The core material using woven fabric or non-woven fabric is provided with through-holes, and the through-holes are filled with conductive paste. When pressure is applied thereto, the through-holes are deformed or widened because they are pushed by metal particles included in the conductive paste.

On the other hand, since a member using a film as the core material does not have a space inside thereof, the member has incompressibility. The reason thereof is as follows. The core material using a film is provided with through-holes, and the through-holes are filled with conductive paste. When pressure is applied thereto, the diameter of the through-hole is not substantially changed.

When woven fabric or non-woven fabric using glass fibers is used as the core material and when through-holes are formed by laser or the like, tip ends of the woven fabric or non-woven fabric made of glass fibers in the periphery of the holes may be melted and solidified. Also in this case, however, the core material has compressibility. The reason thereof is as follows. Glass fibers melted to be integrated with each other by laser or the like are present only in the periphery of the holes, and glass fibers in other parts (that is to say, a part that is little apart from the thorough holes formed by laser) are just entangled with each other. This is also because all of the glass fibers exposed to the periphery of the holes are not melted to be integrated with each other.

Furthermore, in a case of non-woven fabric using glass fibers, a portion in which fibers are entangled with each other may be fixed. Also in this case, however, a member including the non-woven fabric as the core material has compressibility.

Since incompressible member 220 does not have air bubble portions or the like for expressing compressibility inside thereof, it has excellent incompressibility.

When the incompressible member is used, via paste can be compressed with high pressure. As a result, via-hole conductor 140 including 74.0 vol % or more and 99.5 vol % or less of metal portion 190, and 0.5 vol % or more and 26.0 vol % or less of resin portion 200 can be produced.

By reducing the volume fraction (vol %) of resin portion 200 that is an insulating component in via-hole conductor 140, the volume fraction (vol %) of metal portion 190 is increased, and via resistance is reduced. The via resistance herein denotes a resistance value of entire via-hole conductor 140. Also, in order to enhance mechanical strength of a via portion, it is preferable to increase the volume fraction of metal portion 190 in via-hole conductor 140.

Furthermore, by increasing a contact area between wiring 120 and via-hole conductor 140, connection resistance between wiring 120 and via-hole conductor 140 is reduced. Therefore, it is preferable to reduce the volume fraction of resin portion 200 in an interface portion between wiring 120 and via-hole conductor 140.

Since the configuration of the present exemplary embodiment allows the specific resistance of via-hole conductor 140 to be 1.00×10⁻⁷ Ω·m or more and 5.00×10⁻⁷ Ω·m or less, the via resistance is stabilized.

Furthermore, in the present exemplary embodiment, an alloying reaction between copper and tin is almost perfectly completed.

Note here that resin portion 200 constituting via-hole conductor 140 is made of a cured product of curable resin. The curable resin is not particularly limited, but specifically, it is preferable to use, for example, a cured product of epoxy resin having an excellent heat-resistant property and a low coefficient of linear expansion.

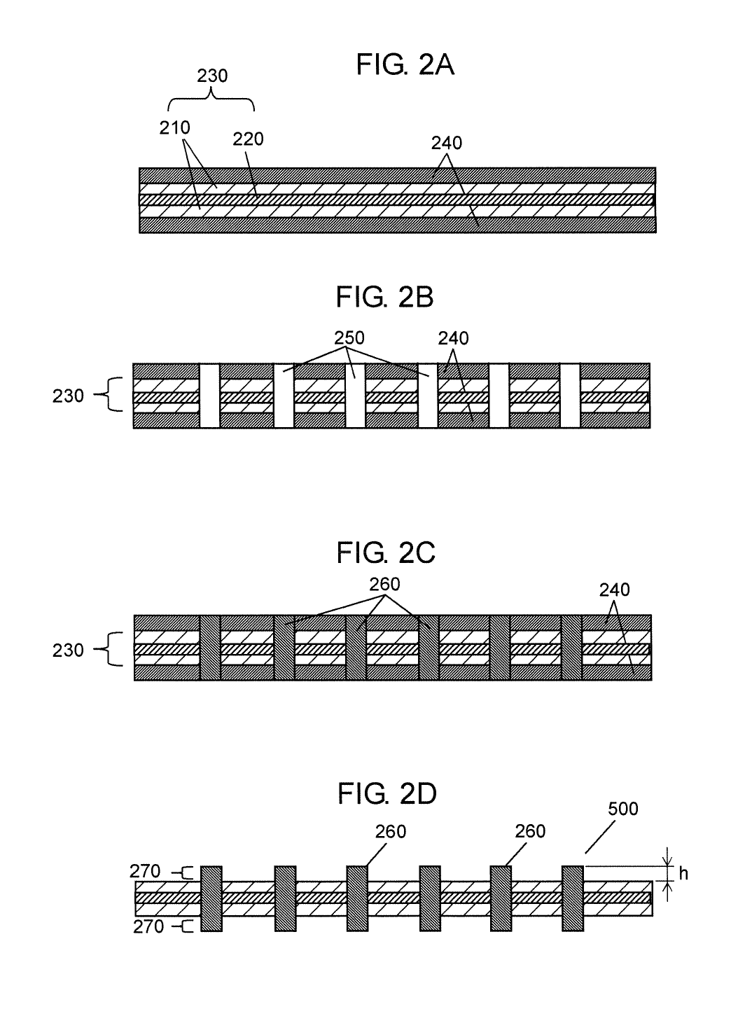

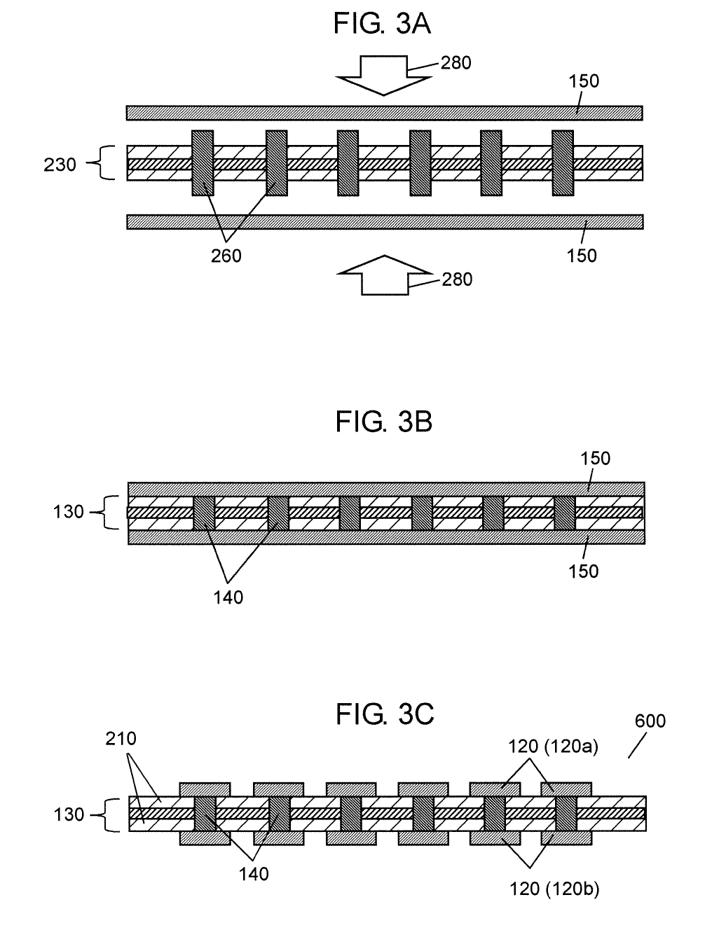

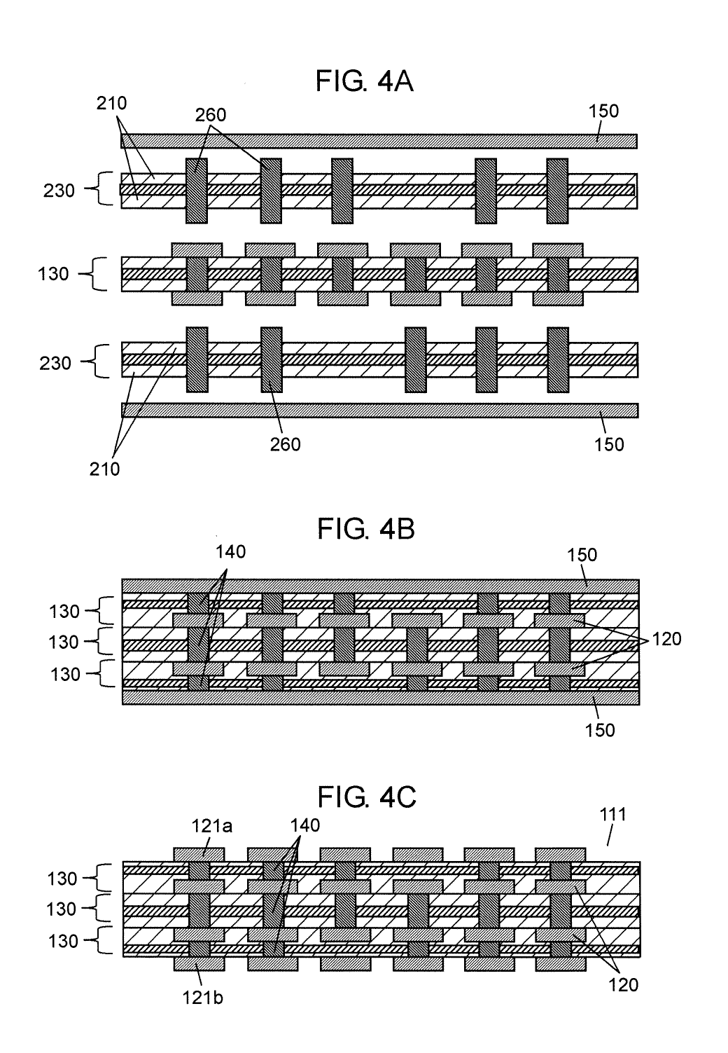

One example of a method for manufacturing wiring board 600 and multilayer wiring board 111 is described. FIGS. 2A to 2D and 3A to 3C are sectional views showing a method for manufacturing wiring board 600. FIGS. 4A to 4C are sectional views showing a method for manufacturing multilayer wiring board 111. Uncured base material 230 (base material) includes incompressible member 220 having a thickness of 55 μm or less, and uncured-state thermosetting adhesive layers 210 formed on both surfaces of incompressible member 220.

Firstly, as shown in FIG. 2A, protective films 240 are attached to both surfaces of uncured base material 230. Incompressible member 220 has a sufficient insulation property even if it has a thickness of 50 μm or less, 30 μm or less, 15 μm or less, and, furthermore, 6 μm or less.

Examples of incompressible member 220 include a polyimide film, a liquid crystal polymer film, a polyether ether ketone film, and the like. Particularly preferable among them is the polyimide film. However, incompressible member 220 is not particularly limited as long as it is a resin sheet that is resistant to soldering temperatures.

Examples of thermosetting adhesive layer 210 include an uncured adhesive layer made of, for example, epoxy resin. Furthermore, in order to thin the multilayer wiring board, the thickness of the thermosetting adhesive layer per one surface is preferably 1 μm or more and 30 μm or less, and further preferably 5 μm or more and 10 μm or less.

Examples of the protective film include resin films of PET (polyethylene terephthalate), PEN (polyethylene naphthalate), and the like. The thickness of the resin film is preferably 0.5 μm or more and 50 μm or less, and further preferably 1 μm or more and 30 μm or less. When the resin film has such a thickness, protruding portions made of via paste and having a sufficient height are allowed to protrude by peeling off the protective films as mentioned below.

Examples of a method for attaching protective film 240 onto uncured base material 230 include a method of directly attaching the film by using surface tackiness (or bonding force) of uncured base material 230 or thermosetting adhesive layer 210 on the surface of uncured base material 230.

Next, as shown in FIG. 2B, through-holes 250 are formed by perforating uncured base material 230 provided with protective films 240 from the outer side of either of protective films 240. For the perforating, various methods such as drilling a hole, or the like, can be used, in addition to a non-contact processing method using carbon dioxide gas laser, YAG laser, or the like. The diameter of the through-hole is 10 μm or more and 500 μm or less, furthermore, 50 μm or more and 300 μm or less, and 80 μm or more and 120 μm or less.

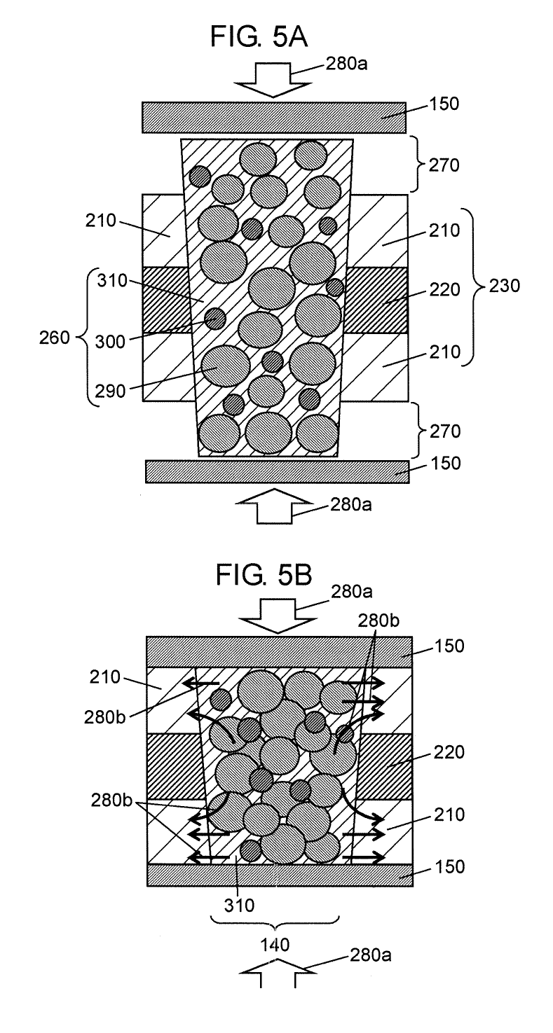

Next, as shown in FIG. 2C, through-holes 250 are filled with via paste 260. Via paste 260 includes copper particles 290, Sn—Bi solder particles 300 containing Sn and Bi, and thermosetting resin component (organic component) 310 such as epoxy resin (see FIG. 5A).

A method for filling via paste 260 is not particularly limited. Examples of the method include a screen printing method.

Next, as shown in FIG. 2D, by peeling off protective film 240 from the surfaces of uncured base material 230, a part of via paste 260 is allowed to protrude as protruding portion 270 from each through-hole 250 (see FIG. 2B), and thus substrate 500 is produced. Height “h” of protruding portion 270 is, for example, 0.5 μm or more and 50 μm or less, and further preferably 1 μm or more and 30 μm or less, depending on the thickness of the protective film. When protruding portion 270 is too high, in the below-mentioned pressurization process, paste may overflow to the periphery of through-hole 250 on the surface of uncured base material 230, and thereby the surface smoothness may be lost. Furthermore, when protruding portion 270 is too low, pressure may not be sufficiently applied to the filled via paste in the below-mentioned pressurization process.

Next, as shown in FIG. 3A, metal foil 150 is disposed on uncured base material 230, and pressure is applied thereto in a direction shown by arrows 280. When pressure is applied, force is applied to protruding portions 270 by way of metal foil 150, so that via paste 260 filled into through-hole 250 is compressed with high pressure.

Since incompressible member 220 is used as a part of uncured base material 230, at the time when pressure is applied as shown by arrows 280 (furthermore, at the time when heating is carried out), the diameter of through-hole 250 is not widened, so that strong pressure is applied to via paste 260. As a result, intervals between copper particles and Sn—Bi particles included in via paste 260 are narrowed, and the particles are brought into close contact with each other. Consequently, the ratio of the resin portion in via paste 260 is reduced. In other words, the ratio of the metal portion in via paste 260 is increased.

Then, when heat is applied in a state in which compression state is kept, an alloying reaction occurs and then, metal portion 190 and resin portion 200 (see FIG. 1B) are formed. Furthermore, thermosetting resin component 310 is made into resin portion 200 by heat curing, and via-hole conductor 140 is formed (see, FIG. 1B). With the above-mentioned processes, as shown in FIG. 3B, uncured base material 230 is made into electric insulating base material 130. Herein, metal portion 190 includes first metal region 160 mainly composed of copper, second metal region 170 mainly composed of a tin-copper alloy, and third metal region 180 mainly composed of bismuth (see FIG. 1B).

In this alloying reaction, the size (or volume % or weight %) of second metal region 170 is made to be larger than that of first metal region 160. Furthermore, the size (or volume % or weight %) of second metal region 170 is made to be larger than that of third metal region 180. As a result, reliability of via-hole conductor 140 is enhanced and the strength thereof is increased.

Furthermore, when first metal region 160 and third metal region 180 are scattered in a state in which they are not brought into contact with each other in second metal region 170, the reliability of via-hole conductor 140 can be enhanced.

Furthermore, second metal region 170 includes intermetallic compounds Cu₆Sn₅ and Cu₃Sn, and the ratio of Cu₆Sn₅/Cu₃Sn is made to be 0.001 or more and 0.100 or less. Thereby, the reliability of via-hole conductor 140 can be enhanced.

Pressurizing conditions are not particularly limited, but it is preferable that a die temperature is set at temperatures from an ordinary temperature (20° C.) to a temperature lower than the melting point of Sn—Bi solder particle. Furthermore, in this pressurization process, in order to allow curing of thermosetting adhesive layer 210 to proceed, a hot press that has been heated to a temperature necessary for allowing the curing to proceed may be used.

Next, a photoresist film is formed on the surface of metal foil 150. Then, the photoresist film is exposed to light via a photomask. Thereafter, development and rinsing are carried out, and the photoresist film is selectively formed on the surface of metal foil 150. Then, metal foil 150 that is not covered with the photoresist film is removed by etching. Thereafter, the photoresist film is removed. In this way, wiring 120a (first wiring) and wiring 120b (second wiring) are formed. Thus, wiring board 600 is obtained. For formation of the photoresist film, liquid resist may be used or a dry film may be used.

FIGS. 4A to 4C are sectional views for illustrating a method for making wiring board 600 produced in FIG. 3C be more multilayered.

As shown in FIG. 4A, substrates 500 (see FIG. 2D) each having protruding portions 270 are disposed on both sides of wiring board 600 that has been produced in FIG. 3C. Then, substrates 500 and wiring board 600 are sandwiched in a pressing die (not shown) by way of metal foil 150, pressed and heated. Thereby, a laminated body shown in FIG. 4B is obtained. Thereafter, as shown in FIG. 4C, metal foil 150 is subjected to patterning so that wiring 121a on the upper layer and wiring 121b on the lower layer are formed. Thus, multilayer wiring board 111 is configured.

According to the above-mentioned processes, multilayer wiring board 111 in which wiring 121a on the upper layer and wiring 121b on the lower layer are coupled to each other by way of via-hole conductor 140 is obtained. By making multilayer wiring boards 111 be more multilayered, multilayer wiring board 110 as shown in FIG. 1A in which a plurality of wirings are coupled to each other is obtained.

Next, with reference to FIGS. 5A and 5B, a state in which organic components included in via paste 260 are exhausted from via paste 260 to the outside is described. When the ratio of the organic components included in via paste 260 is reduced, the ratio of the metal component is increased. As a result, an alloying reaction, furthermore, a formation reaction of an intermetallic compound is completed in a short time.

FIGS. 5A and 5B are schematic sectional views of the vicinity of through-hole 250 which is filled with via paste 260 in uncured base material 230 before and after compression, respectively. FIG. 5A shows a state before compression, and FIG. 5B shows a state after compression. FIG. 5A corresponds to an enlarged view of via paste 260 of FIG. 3A.

The average particle diameter of copper particle 290 is preferably 0.1 μm or more and 20 μm or less, and further preferably 1 μm or more and 10 μm or less. When the average particle diameter of copper particle 290 is too small, the tap density (JIS X 2512) of copper particles 290 is reduced. Therefore, through-hole 250 (see FIG. 2B) cannot be easily filled with the via paste including copper particles 290 with a high density, and the cost tends to be increased. On the other hand, when the average particle diameter of copper particle 290 is too large, when via-hole conductor 140 having a small diameter of 100 μm or less and furthermore 80 μm or less is intended to be formed, filling tends to be difficult.

Examples of the particle shape of copper particle 290 include a spherical shape, a flat shape, a polygonal shape, a scale shape, a flake shape, or a shape having protrusions on the surface, but the particle shape is not necessarily limited to these shapes. Furthermore, the particles may be primary particles or secondary particles.

Sn—Bi solder particle 300 denotes solder particle 300 containing Sn and Bi.

Furthermore, wettability, flowability, or the like, may be improved by adding indium (In), silver (Ag), zinc (Zn), or the like, into solder particle 300. The content rate of Bi in Sn—Bi solder particle 300 is preferably 10% or more and 58% or less, and further preferably, 20% or more and 58% or less. Furthermore, a melting point (eutectic point) is preferably 75° C. or higher and 160° C. or lower, and further preferably, 135° C. or higher and 150° C. or lower. As Sn—Bi solder particle 300, combination of two types or more of different particles may be used. Particularly preferable among them is Sn-58Bi solder particle 300, which is lead-free solder having a eutectic point that is low as 138° C., from the environmental viewpoint.

The average particle diameter of Sn—Bi solder particle 300 is preferably 0.1 μm or more and 20 μm or less, and further preferably 2 μm or more and 15 μm or less. When the average particle diameter of the Sn—Bi solder particle is too small, the specific surface area becomes larger and the ratio of an oxide film on the surface is increased, and therefore melting does not easily occur. On the other hand, when the average particle diameter of Sn—Bi solder particle is too large, via paste 260 cannot be easily filled into through-holes 250.

Examples of thermosetting resin component 310 include glycidylether-type epoxy resin, alicyclic epoxy resin, glycidyl amine type epoxy resin, glycidyl ester type epoxy resin, other modified epoxy resin, or the like.

Furthermore, thermosetting resin component 310 may include a curing agent. Types of the curing agent are not particularly limited, but it is preferable to use a curing agent containing an amine compound having at least one or more hydroxyl groups in a molecule. Such a curing agent acts as a curing catalyst of epoxy resin, and reduces the oxide film that is present on the surface of copper particles and Sn—Bi solder particles 300, thereby lowering contact resistance at the time of bonding. An amine compound having a boiling point that is higher than the melting point of the Sn—Bi solder particle is particularly preferable because it lowers the contact resistance at the time of bonding.

Examples of such amine compounds include 2-2-methylaminoethanol, N, N-diethylethanolamine, N, N-dibutylethanolamine, N-methylethanolamine, N-methyldiethanolamine, N-ethylethanolamine, N-butylethanolamine, diisopropanolamine, N,N-diethylisopropanolamine, 2,2′-dimethylaminoethanol, triethanolamine, and the like.

Via paste 260 is obtained by mixing copper particles 290, Sn—Bi solder particles 300 containing Sn and Bi, and thermosetting resin component 310 such as epoxy resin. Specifically, for example, via paste 260 is obtained by adding copper particles and Sn—Bi solder particles into resin varnish containing epoxy resin, a curing agent and a predetermined amount of an organic solvent, and mixing the obtained product by using, for example, a planetary mixer.

The ratio of thermosetting resin component 310 in via paste 260 is preferably 0.3 mass % or more and 30 mass % or less, and further preferably 3 mass % or more and 20 mass % or less from the viewpoint of obtaining a low resistance value and securing sufficient workability.

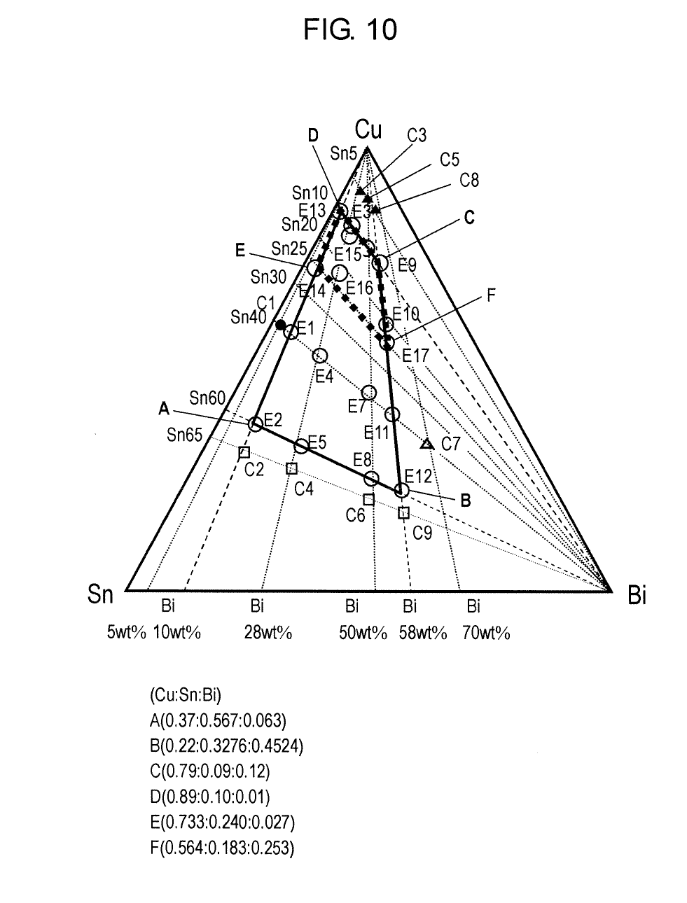

Furthermore, as a blending ratio of copper particles 290 and Sn—Bi solder particles 300 in via paste 260, it is preferable that copper particles 290 and Sn—Bi solder particles 300 are contained such that the weight ratio of Cu, Sn and Bi is in a range of a region surrounded by a quadrangle having apexes A, B, C, and D in a ternary diagram as shown in FIG. 10 mentioned below. For example, when Sn-58Bi solder particles 300 are used as Sn—Bi solder particles 300, the content rate of copper particles 290 with respect to the total amount of copper particles 290 and Sn-58Bi solder particles 300 is preferably 22 mass % or more and 80 mass % or less, and further preferably 40 mass % or more and 80 mass % or less.

As shown in FIG. 5A, protruding portion 270 protruding from through-hole 250 formed in uncured base material 230 is pressed by way of metal foil 150 as shown in arrows 280a. Then, as shown in FIG. 5B, via paste 260 filled into through-hole 250 (see FIG. 2B) is compressed. Note here that at this time, a considerable part of thermosetting resin component 310 in via paste 260 is pushed out to the outside from through-hole 250 as shown by arrow 280b. Then, copper particles 290 and Sn—Bi solder particles 300 are alloyed by heating, and the metal portion after alloying is 74 vol % or more, 80 vol % or more, and furthermore, 90 vol % or more in the via-hole conductor.

Incompressible member 220 is used so that through-hole 250 (see FIG. 2B) is not easily widened or deformed due to pressure from via paste 260 when via paste 260 is filled, pressed and heated.

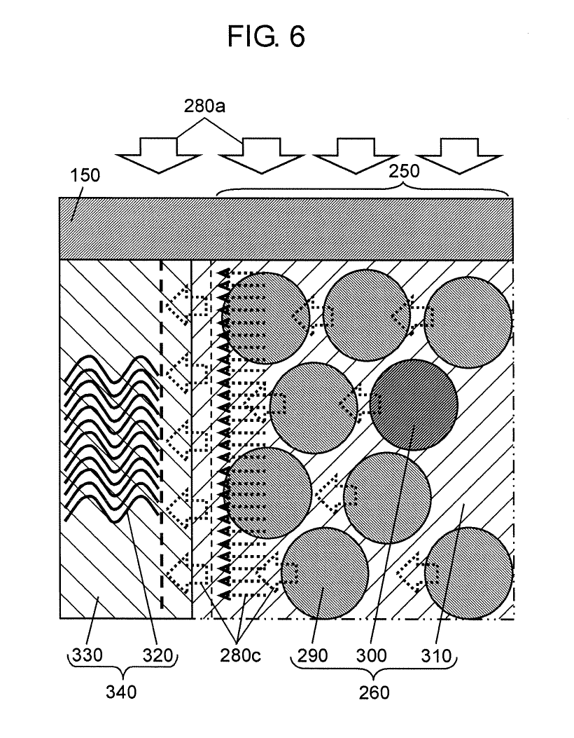

With reference to FIGS. 6 to 8, a mechanism for reducing the organic component in via paste 260 is described.

FIG. 6 is a schematic view showing a state of the via paste when a member having compressibility is used as the electric insulating base material. As compressible member 340, prepreg is used. The prepreg includes, for example, a glass fiber, an aramid fiber, or the like, as core material 320, and core material 320 is impregnated with semi-cured resin 330 made of, for example, epoxy resin. The prepreg expresses compressibility by the presence of a gap among fibers of the core material, or a gap between the core material and the semi-cured resin, or air space (for example, air bubbles) included in the semi-cured resin. That is to say, a cured product of the prepreg is incompressible but the prepreg has compressibility. This is because when the prepreg is heated and compressed, the semi-cured resin is softened to fill the gap among fibers of the core material, the gap between the core material and the resin, or the air space (for example, air bubbles) included in the resin.

Since compressible member 340 has air bubbles (or voids), or the like, inside thereof, when it is pressed, the thickness thereof is compressed by about 10% to 30%.

Through-hole acting as a via is formed in compressible member 340 and filled with via paste to provide a protruding portion. Then, when the pressure is applied thereto, a diameter (or a sectional area) of the through-hole after pressure is applied becomes larger by about 10% to 20% as compared with the diameter before pressure is applied.

This is because a part of glass fibers is cut when the through-hole is formed. That is to say, when prepreg including woven fabric or non-woven fabric is used as the core material, sufficient pressurization and compression cannot be carried out in some cases.

In FIG. 6, arrow 280c shows a state in which via paste 260 is pressurized and compressed as shown by arrow 280a, so that the diameter of through-hole 250 is increased (or the diameter of through-hole 250 is widened or deformed).

When compressible member 340 as shown in FIG. 6 is used, pressure shown by arrow 280a in FIG. 6 is applied to via paste 260, and the diameter of through-hole 250 (see FIG. 2B) is widened by a part corresponding to a volume of protruding portion 270 of via paste 260 by pressure shown by arrow 280c. Therefore, even if the pressure shown by arrow 280a is increased, it is difficult to pressurize and compress via paste 260. As a result, it is difficult to move thermosetting resin component 310 in via paste 260 into uncured base material 230 (see FIG. 5A). Therefore, the rate of the volume fraction of thermosetting resin component 310 in via paste 260 is hardly changed before and after pressure is applied shown by arrow 280a.

Note here that a volume fraction in the case where spherical bodies are randomly packed in a container is known to be about 64% at maximum as “random close packing” (see, for example, Nature 435, 7195 (May 2008), Song et al.). When compressible member 340 is used for the electric insulating base material in this way, even if the packing density (furthermore, the volume fraction) of copper particles 290 and solder particles 300 contained in via paste 260 is to be enhanced, it is difficult to enhance the volume fraction from the viewpoint of the random close packing. Therefore, even when protruding portion 270 is pressurized and compressed to an extent that copper particles 290 and solder particles 300 are deformed and brought into surface contact with each other, it is difficult to exclude thermosetting resin components 310 remaining in the gap among a plurality of copper particles 290 and a plurality of solder particles 300 to the outside of via paste 260.

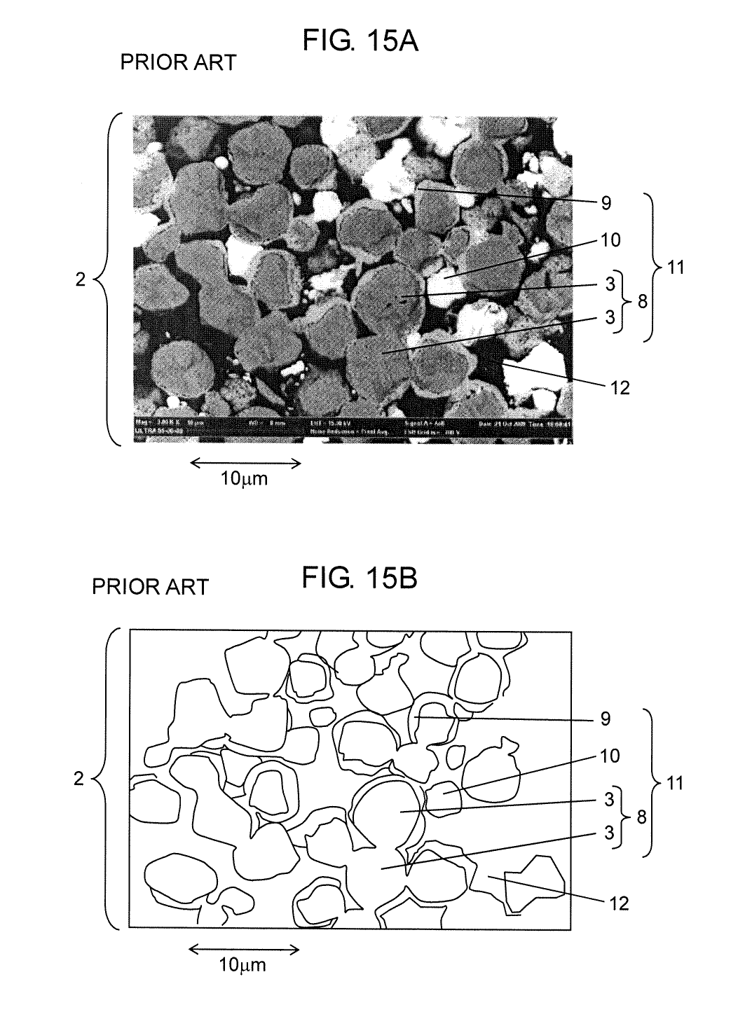

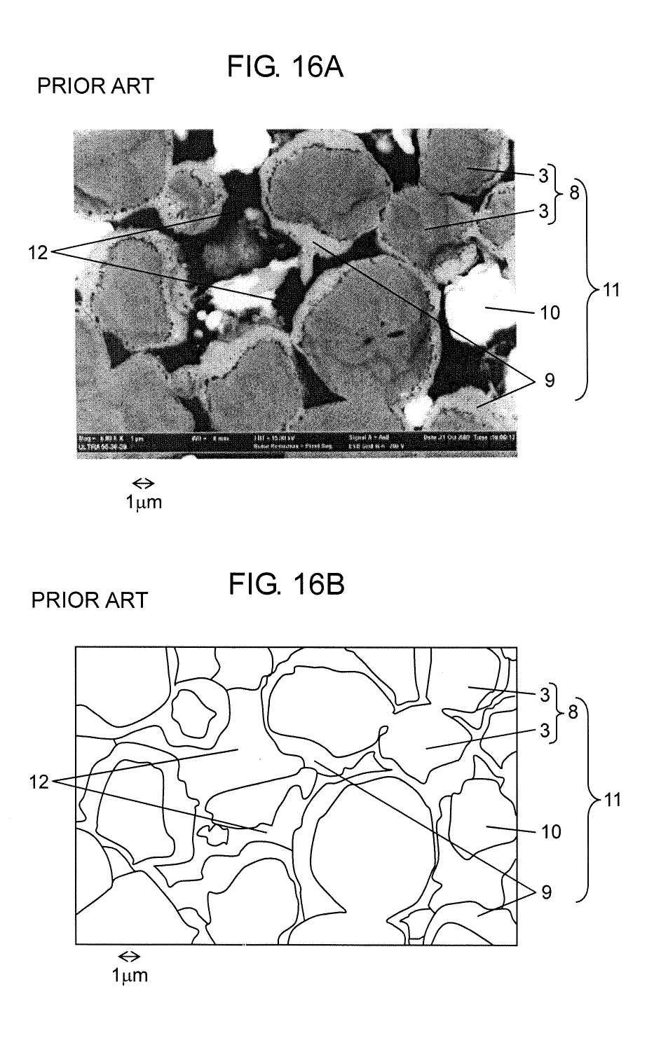

As a result, a state shown in FIGS. 14 to 16B is obtained. Consequently, even if pressure is increased, it is difficult to make the volume fraction of metal portion 190 in via-hole conductor 140 be higher than 70 vol %.

As mentioned above, in compressible member 340, the diameter of through-hole 250 is widened or deformed by pressure from via paste 260. Therefore, even when high pressure is applied, via paste 260 may not be sufficiently compressed.

On the other hand, when an incompressible member (for example, a film base material) is used, even when a through-hole acting as a via is provided in a thermosetting adhesive layer an incompressible member, the through holes are filled with via paste to provide a protruding portion, and then pressure is applied thereto, a diameter (or a sectional area) of the through hole after pressure is applied is hardly changed as compared with that before pressure is applied, or the changed amount is suppressed to less than 3%. Then, since the diameter or the sectional area of the through-hole is not changed before and after the through-hole is filled with via paste, the via paste can be sufficiently pressurized and compressed without using specific equipment. This is because when the incompressible member is used, even when a part of the incompressible member is cut by the through-hole, the incompressible member is hardly melted or widened.

However, even when a heat-resistant film like a polyimide film is used, but when the thickness thereof is large as 70 μm, via paste 260 may not be compressed sufficiently even with high pressure applied by using protruding portion 270.

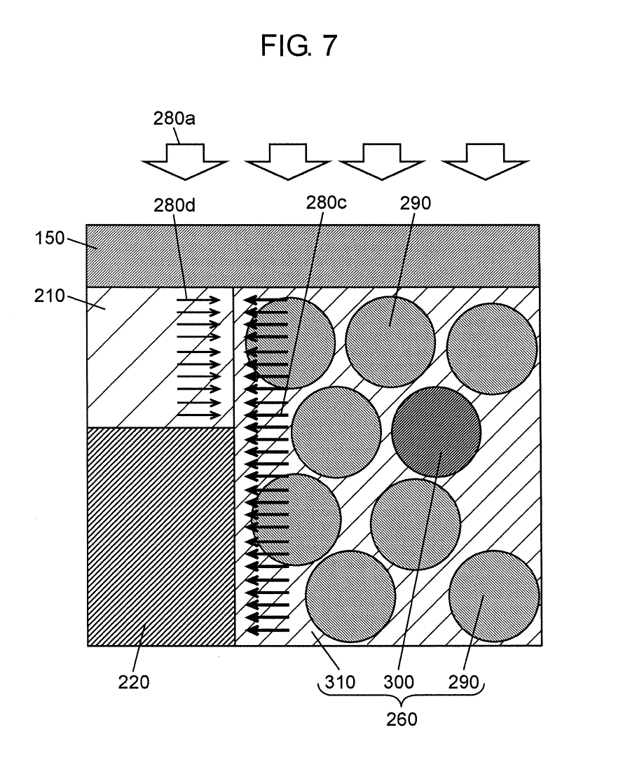

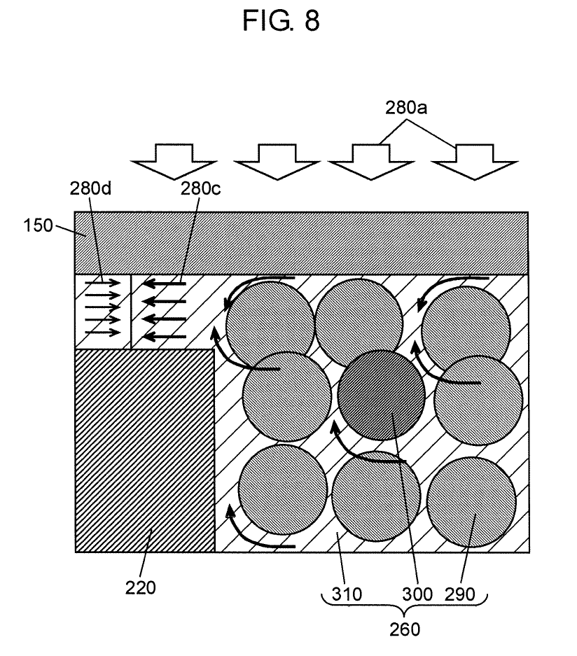

FIGS. 7 and 8 are schematic views respectively showing a state of via paste when an incompressible member is used.

When incompressible member 220 such as a heat-resistant film is used for uncured base material 230, a fluid component (for example, an insulating component such as an organic component) of thermosetting resin component 310 in via paste 260 can be excluded to the outside of via-hole conductor 140. As a result, the volume fraction of thermosetting resin component 310 in via paste 260 can be reduced.

As shown in FIGS. 7 and 8, even when pressure as shown by arrow 280a is applied to via paste 260, the diameter of through-hole 250 (see FIG. 2B) is hardly widened. As a result, as the pressure shown by arrow 280a is increased, copper particles 290 and solder particles 300 which are included in via paste 260 are deformed and brought into surface contact with each other in a wide area. Therefore, the volume fraction of metal portion 190 in via-hole conductor 140 can be made to be more than 70 vol % and furthermore 80 vol % or more and 90 vol % or more.

Note here that in order to deform and bring copper particles 290 and solder particles 300 into surface contact with each other in a wide area, it is preferable that rigidity of copper particle 290 and rigidity of solder particle 300 are made to be different from each other. For example, by making the rigidity of solder particle 300 be lower than that of copper particle 290, it is possible to reduce powders which slide (or slip) each other. As a result, when pressurizing and compressing shown in FIGS. 7 and 8 are carried out, solder particle 300 is deformed while it maintains a state in which it is interposed in a plurality of copper particles 290, and a fluid component (for example, an insulating component such as organic component) in via paste 260 can be excluded to the outside of via-hole conductor 140. As a result, it is possible to further reduce the volume fraction of thermosetting resin component 310 in via paste 260.

As shown in FIG. 7 mentioned above, when via paste 260 is pressurized and compressed from the outer side of metal foil 150 as shown in arrow 280a, the fluid component in via paste 260, that is, thermosetting resin component 310 flows into thermosetting adhesive layer 210 provided on the surface of incompressible member 220. As a result, as shown in FIG. 8, the filling rate of copper particles 290 and solder particles 300 in via paste 260 is increased. Note here that FIGS. 7 and 8 do not show a state in which copper particles 290 or solder particles 300 are compressed, deformed, and brought into surface contact with each other. Furthermore, FIGS. 7 and 8 do not show protruding portion 270 by via paste 260 formed in metal foil 150.

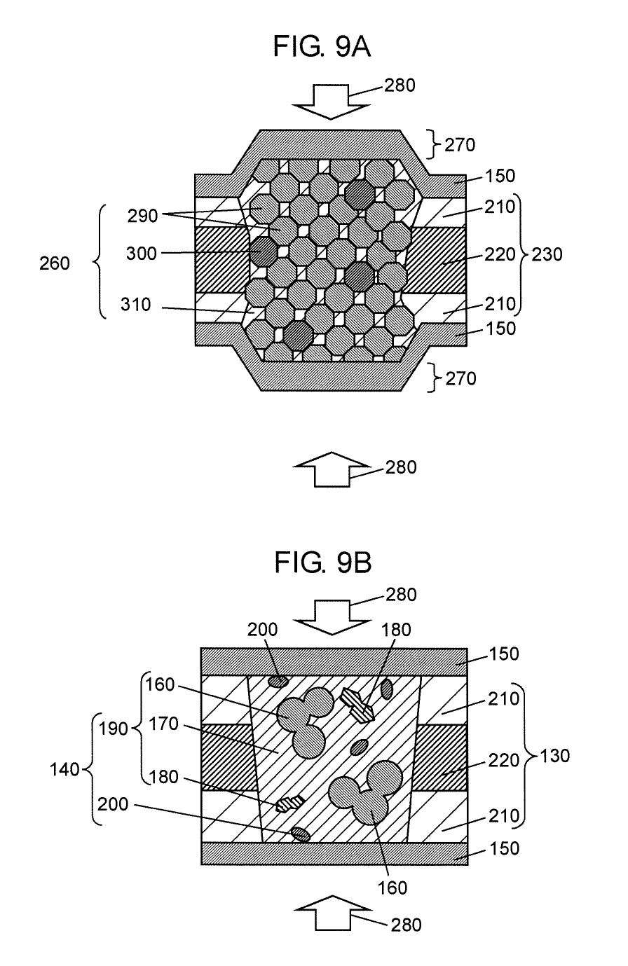

FIG. 8 shows a state in which pressure (arrow 280c) by thermosetting resin component 310 in via paste 260 exceeds pressure (arrow 280d) from thermosetting adhesive layer 210, and thermosetting resin component 310 flows to the outside of through-hole 250. When incompressible member 220 is used, it is possible to exhaust thermosetting resin component 310 in via paste 260 to the outside of via paste 260, and to greatly reduce the volume fraction of thermosetting resin component 310 in via paste 260. Then, the volume fraction of metal components such as copper particles 290 and solder particles 300 in via paste 260 is increased by the reduced amount of thermosetting resin component 310 contained in via paste 260. As a result, the volume fraction of metal portion 190 in via-hole conductor 140 (see FIGS. 1B and 9B) can be increased to 74 vol % or more.

That is to say, when the incompressible base material is used for uncured base material 230, the diameter of through-hole 250 is hardly changed between before and after compression. Therefore, according to protruding of via paste 260, via paste 260 can be highly compressed.

Note here that a difference between the diameter (or the sectional area) of the through-hole before pressure is applied and that after pressure is applied is preferably less than 3% and further preferably less than 2%.

Thus, in the present exemplary embodiment, the volume fraction of metal portion 190 after copper particles 290 and solder particles 300 are alloyed can be made to be 74.0 vol % or more and 99.5 vol % or less. Furthermore, in via-hole conductor 140 for electrically connecting a plurality of wirings to each other, the volume fraction of resin portion 200 that is a part excluding metal portion 190 can be reduced to 0.5 vol % or more and 26.0 vol % or less. Herein, resin portion 200 only needs to be a resin portion included in via-hole conductor 140 and may not be thermosetting resin component 310 contained in via paste 260. Furthermore, thermosetting resin component 310 in via paste 260 and thermosetting adhesive layer 210 may be compatible with each other or may be dissolved into each other.

When via paste 260 is filled into through-hole 250 formed in incompressible member 220 and thermosetting adhesive layer 210, and pressed, the content (or volume fraction) of thermosetting resin component 310 in the via paste can be further reduced. Therefore, it is possible to increase the filling rate (or volume fraction) of copper particles 290, solder particles 300, or the like, in via paste 260. As a result, the contact area between copper particles 290 and solder particles 300 is increased, and an alloying reaction is promoted. Thus, the metal portion in via-hole conductor 140 can be increased.

Next, a state in which the alloying reaction between copper particles and solder particles is promoted by reducing the volume fraction of thermosetting resin component 310 is described.

FIG. 9A is a schematic view showing a state of via paste before the alloying reaction. FIG. 9B is a schematic view showing a state of the via paste after the alloying reaction.

In FIG. 9A, copper particles 290 and solder particles 300 are compressed to each other as shown by arrows 280 and they are packed with a high density. At this time, it is desirable that copper particles 290 and solder particles 300 are deformed and brought into surface contact with each other. As an area in which copper particles 290 and solder particles 300 are brought into contact with each other is larger, an alloying reaction between copper particles 290 and solder particles 300 (furthermore, a formation reaction of an intermetallic compound) proceeds in a shorter time and uniformly.

Note here that the volume fraction of thermosetting resin component 310 included in via paste 260 is 0.5 vol % or more and 26 vol % or less (furthermore, 20 vol % or less and yet furthermore, 10 vol % or less).

As shown in FIG. 9A, by compression-bonding metal foil 150 to uncured base material 230, and applying predetermined pressure to protruding portion 270 of via paste 260 by way of metal foil 150, via paste 260 is pressurized and compressed. Thus, copper particles 290, as well as copper particles 290 and solder particles 300 can be brought into surface contact with each other so as to promote the alloying reaction.

Protruding portions 270 are formed on the upper and lower surfaces of via paste 260 in FIG. 9A. Furthermore, the upper and lower surfaces of via-hole conductor 140 of FIG. 9B are flat without having protruding portions. It is desirable that the upper and lower surfaces of via paste 260 are flat in this way after the alloying reaction. Conventionally, when an incompressible member is used, the protruding portion of the via-hole conductor may remain also after the alloying reaction, thus making it difficult to mount a component. However, as in the present exemplary embodiment, by allowing the alloying reaction to proceed at an extremely high speed, the volume fraction of metal portion 190 in via-hole conductor 140 can be made to be 74.0 vol % or more and the via-hole conductor can be made to be flat. Furthermore, the volume fraction of resin portion 200 in via-hole conductor 140 can be made to be 26.0 vol % or less. Note here that the height of protruding portion 270 (“h” in FIG. 2D) is desirably 2 μm or more, and further desirably 5 μm or more, or the height is 0.5 times or more as large as the thickness of metal foil 150. When the size of protruding portion 270 is smaller than 2 μm, or less than 0.5 times as large as the thickness of metal foil 150, even when an incompressible member is used for electric insulating base material 130, the volume fraction of copper particles 290, solder particles 300, or the like, in via paste 260 may not able to be 74 vol % or more.

Note here that the particle diameter of copper particle 290 and the particle diameter of solder particles 300 may be made to be different from each other, and copper particles 290 having different particle diameters may be mixed with each other. However, in such cases, a specific surface area of powder is increased, resulting in increasing the viscosity of via paste 260. As a result, although the volume fraction of the total of copper particles 290 and solder particles 300 in via paste 260 can be increased, the viscosity of via paste 260 is increased, and thus filling property of through-hole 250 may be affected. Therefore, it is preferable that the diameter of copper particle 290 and the diameter of solder particle 300 are the same level as each other.

In order to deform and bring copper particles 290 and solder particles 300 into surface contact with each other, it is desirable that copper particles 290 or solder particles 300 and copper particles 290 are pressurized and compressed such that they are plastically deformed to each other.

It is preferable that heating is carried out at a predetermined temperature in a state in which a compression bonding state is maintained as shown by arrows 280 in FIGS. 9A and 9B, so that Sn—Bi solder particles 300 are partially melted. When heating is carried out in the pressurization process, the total time of the pressurization process and heating process can be shortened, so that productivity can be increased.

FIG. 9B shows a state after copper particles 290 and solder particles 300, which are deformed and brought into surface contact with each other, are subjected to an alloying reaction (furthermore, a formation reaction of an intermetallic compound). Via-hole conductor 140 includes metal portion 190 and resin portion 200. Metal portion 190 includes first metal region 160 mainly composed of copper, second metal region 170 mainly composed of a tin-copper alloy, and third metal region 180 mainly composed of bismuth. Metal portion 190 and resin portion 200 constitute via-hole conductor 140.

Thus, via-hole conductor 140 is formed as shown in FIG. 9B. Resin portion 200 is cured resin including epoxy resin. Second metal region 170 has larger sectional area and volume fraction or weight fraction than those of first metal region 160. Furthermore, second metal region 170 has larger sectional area and volume fraction or weight fraction than those of third metal region 180.

Metal foils 150 forming a plurality of wirings 120 are electrically coupled to each other by way of second metal region 170. When first metal region 160 and third metal region 180 are scattered in a state in which they are not brought into contact with each other in second metal region 170, the reliability of via-hole conductor 140 is enhanced. In addition, when second metal region 170 includes intermetallic compounds Cu₆Sn₅ and Cu₃Sn and the ratio of Cu₆Sn₅/Cu₃Sn is made to be 0.001 or more and 0.100 or less, the reliability of via-hole conductor 140 is enhanced.

Pressurization and compression shown by arrows 280 are continued also during the alloying reaction, and thereby the height of protruding portion 270 in metal foil 150 after the alloying can be lowered. The height of protruding portion 270 before the alloying reaction is lowered after the alloying reaction, and thereby the volume fraction of resin portion 200 in via-hole conductor 140 can be reduced, and variation in the thickness of multilayer wiring board 110 can be reduced. Furthermore, since flatness or smoothness of multilayer wiring board 110 can be improved, a mounting property of a bare chip such as a semiconductor chip can be enhanced.

In via-hole conductor 140 formed through a reaction between copper particles 290 and solder particles 300, second metal region 170 includes intermetallic compounds Cu₆Sn₅ and Cu₃Sn. Herein, when the ratio of Cu₆Sn₅/Cu₃Sn is reduced to 0.001 or more and 0.100 or less, for example, generation of voids 5a such as Kirkendall voids (see FIG. 14) can be suppressed.

In order to make the ratio of Cu₆Sn₅/Cu₃Sn be 0.001 or more and 0.100 or less, it is desirable that the contact area between copper particle 290 and solder particle 300 is large. At the time when the alloying reaction (or a formation reaction of an intermetallic compound) is carried out, the volume fraction of thermosetting resin component 310 in via paste 260 is desirably 26 vol % or less (further desirably, 20 vol % or less, and yet further desirably, 10 vol % or less). The smaller the volume fraction of thermosetting resin component 310 is, the larger the contact area between copper particles 290 and solder particles 300 becomes. Thus, the alloying reaction becomes uniform. As a result, in the second metal region including the intermetallic compounds Cu₆Sn₅ and Cu₃Sn, the ratio of Cu₆Sn₅/Cu₃Sn can be suppressed to 0.100 or less. As mentioned above, when a member having incompressibility is used as uncured base material 230, the density of copper particles 290 and Sn—Bi solder particles 300 filled into through hole 250 is increased.

Furthermore, it is useful that compressed via paste 260 is heated in a state in which compression is maintained so as to melt a part of Sn—Bi solder particles 300 at a temperature range of not lower than the eutectic temperature of Sn—Bi solder particle 300 to not higher than a temperature that is higher by 10° C. than the eutectic temperature, and subsequently heated to a temperature range of not lower than a temperature that is higher by 20° C. than the eutectic temperature to not higher than 300° C. Such pressurization and heating can promote growth of second metal region 170. In addition, it is preferable that these are carried out in one process including successive compression bonding and heating. When these are carried out in one continuous process, a formation reaction of each metal region can be stabilized, and the structure of the via itself can be stabilized.

For example, in FIG. 9A, high compression is carried out such that the volume fraction of copper particles 290 and solder particles 300 in via paste 260 is 74 vol % or more. Then, in this state, via paste 260 is gradually heated to a temperature that is not lower than the eutectic temperature of Sn—Bi solder particle 300. With this heating, a part of Sn—Bi solder particles 300 is melted at a composition ratio that is melted at the temperature. Then, second metal region 170 mainly composed of tin and a tin-copper alloy is formed on the surface or the periphery of copper particle 290. In this case, a surface-contact portion in which copper particles 290 are brought into surface contact with each other may be changed into a part of second metal region 170. Copper particles 290 and melted Sn—Bi solder particles 300 are deformed and brought into surface contact with each other, thereby Sn in Sn—Bi solder particle 300 and Cu in copper particle 290 are reacted with each other, and a Sn—Cu compound layer (an intermetallic compound) including Cu₆Sn₅ and Cu₃Sn and second metal region 170 mainly composed of a tin-copper alloy are formed. On the other hand, Sn—Bi solder particles 300 continue to maintain a melting state while they are supplemented with Sn from a Sn phase inside thereof, and furthermore, remaining Bi is deposited. Thereby, third metal region 180 mainly composed of Bi is formed. As a result, via-hole conductor 140 having a structure shown in FIG. 9B is obtained.

Note here that in FIG. 9B, it is desirable that the weight ratio of the total of first metal region 160 and second metal region 170 to entire via-hole conductor 140 is 20% or more and 90% or less. When the weight ratio of the total is less than 20%, via resistance may be increased or a predetermined compression state may not be able to be obtained. Meanwhile, it may be technically difficult to make the weight ratio be more than 90%.

Then, when heating is carried out in this state, and a temperature reaches not lower than the eutectic temperature of Sn—Bi solder particle 300, Sn—Bi solder particles 300 start to be partially melted. The composition of the melting solder is determined by a temperature, Sn that is not easily melted at a temperature at the time of heating remains as a Sn solid phase product. Furthermore, copper particles 290 are brought into contact with the melted solder and the surface thereof is wet with the melted Sn—Bi solder, counter diffusion of Cu and Sn proceeds on the interface of the wet portion, and a compound layer of Sn—Cu or the like is formed. Thus, the ratio of second metal region 170 in via-hole conductor 140 can be made to be larger than first metal region 160, and larger than third metal region 180.

On the other hand, when formation of a Sn—Cu compound layer or the like or counter diffusion further proceeds, Sn in the melted solder is reduced. Since Sn that is reduced in the melted solder is supplement from a Sn solid layer, the melting state can be continued to be maintained. When Sn is further reduced and Bi in the ratio of Sn and Bi becomes larger than in Sn-58Bi, segregation of Bi is started, and third metal region 180 as a solid phase product mainly composed of bismuth is deposited and formed.

Note here that well-known solder materials melted at relatively low temperatures include Sn—Pb solder, Sn—In solder, Sn—Bi solder, and the like. Among these materials, In is expensive and Pb has high environmental load. On the other hand, the Sn—Bi solder has a melting point of 140° C. or lower, which is lower than a general solder reflow temperature when an electronic component is surface-mounted. Therefore, when only the Sn—Bi solder as a simple substance is used for a via-hole conductor of a circuit board, solder of the via-hole conductor is melted again at the time of solder reflow, so that the via resistance may be changed.

FIG. 10 is a ternary diagram showing an example of a metal composition in the via paste in accordance with the present exemplary embodiment. The metal composition in the via paste in accordance with the present exemplary embodiment desirably has a weight composition ratio (Cu:Sn:Bi) of Cu, Sn and Bi in a region surrounded by a quadrangle having apexes of A (0.37:0.567:0.063), B (0.22:0.3276:0.4524), C (0.79:0.09:0.12), and D (0.89:0.10:0.01) in the ternary diagram as shown in FIG. 10.

Further desirably, the ratio is in a region surrounded by a quadrangle having apexes of C (0.79:0.09:0.12), D (0.89:0.10:0.01), E (0.733:0.240:0.027), and F (0.564:0.183:0.253). When the ratio is in the region surrounded by the quadrangle having apexes of C (0.79:0.09:0.12), D (0.89:0.10:0.01), E (0.733:0.240:0.027), and F (0.564:0.183:0.253), the via resistance can be reduced. Furthermore, it becomes easy to include intermetallic compounds Cu₆Sn₅ and Cu₃Sn in the second metal region, and to make the ratio of Cu₆Sn₅/Cu₃Sn be 0.100 or less.

Note here that when the via paste having such a metal composition is used, the Sn composition is larger in the composition of Sn—Bi solder particle 300 than in the eutectic Sn—Bi solder composition (Bi: 58% or less and Sn: 42% or more). When such a via paste is used, a part of the solder composition is melted in a temperature range of not higher than a temperature that is higher by 10° C. than the eutectic temperature of the Sn—Bi solder particle, while Sn that is not melted remains. However, remaining Sn is diffused into copper particle surfaces and reacts therewith. As a result, since Sn concentration is reduced from Sn—Bi solder particle 300, remaining Sn is melted. On the other hand, Sn is melted also because heating is continued and a temperature rises, so that Sn that cannot be melted in the solder composition disappears. When heating is further continued, the reaction with the surface of the copper particle proceeds, and thereby third metal region 180 as a solid phase product mainly composed of bismuth is deposited and formed. When third metal region 180 is deposited in this way, the solder in the via-hole conductor is not easily melted again at the time of solder reflow. Furthermore, when solder particle 300 including a Sn—Bi composition having a higher rate of Sn composition is used, a Bi phase remaining in the via can be reduced. Therefore, a resistance value can be stabilized, and the change of the resistance value does not easily occur even after the solder reflow.

A temperature for heating via paste 260 after compression is not particularly limited as long as it is not lower than the eutectic temperature of Sn—Bi solder particle 300 and is in a temperature range at which components constituting uncured base material 230 are not decomposed. Specifically, when Sn-58Bi solder particle whose eutectic temperature is 139° C. is used as the Sn—Bi solder particle, it is preferable that firstly, a part of Sn-58Bi solder particles 300 is melted by heating it at 139° C. or higher and 149° C. or lower, and then gradually heated to a temperature range of 159° C. or higher and 230° C. or lower. Note here that by appropriately selecting a temperature, the thermosetting resin component included in via paste 260 is cured.

Next, the present exemplary embodiment is specifically described with reference to Examples. Note here that the contents of the Examples are not to be in any way construed as limiting the scope of the present exemplary embodiment. Firstly, raw materials used in Examples are described below.
Copper particle (copper particle 290): “1100Y” having an average particle diameter of 5 μm, manufactured by Mitsui Mining & Smelting Co., Ltd.
Sn—Bi solder particle (solder particle 300): particles formed by blending materials so as to have the respective solder compositions (Table 1) listed according to each composition; melting the obtained product; making the obtained powders into powders by an atomization method; and then classifying the obtained product so that the average particle diameter is 5 μm.
Epoxy resin (thermosetting resin component 310): “jeR871” manufactured by Japan Epoxy Resin K.K.
Curing agent: 2-methylaminoethanol having a boiling point of 160° C., manufactured by Nippon Nyukazai Co., Ltd.
Resin sheet (uncured base material 230): Uncured epoxy resin layers (thermosetting adhesive layers 210) having a thickness of 10 μm are formed on both surfaces of a polyimide film (incompressible member 220) having a size of 500 mm (length)×500 mm (width) and thickness of 10 μm to 50 μm.
Protective film (protective film 240): A PET sheet having a thickness of 25 μm
Copper foil (metal foil 150): thickness is 25 μm

### (Production of Via Paste)

A metal component including copper particles and Sn—Bi solder particles at a blending ratio as in Table 1, and a resin component including epoxy resin and a curing agent are blended, and then mixed by using a planetary mixer. Thereby, via paste is produced. The blending ratio of the resin components includes 10 parts by weight of the epoxy resin and 2 parts by weight of the curing agent, both relative to 100 parts by weight of a total of the copper particles and the Sn—Bi solder particles.

### (Manufacture of Multilayer Wiring Board)

Protective films are attached to both surfaces of a resin sheet. Then, 100 holes each having a diameter of 150 μm are perforated by using laser from the outer side of the resin sheet to which protective films are attached.

Next, through-holes are filled with the prepared via paste. Then, the protective films on the both surfaces are peeled off, thereby forming protruding portions each formed of the via paste partially protruding from each of the through-holes.

Next, copper foil is disposed on the both surfaces of the resin sheet so as to cover the protruding portions. Then, release paper is disposed on a die below a hot press machine to form a laminated body of the copper foil and the resin sheet, and pressure of 3 MPa is applied to the laminated body. Then, a temperature of the laminated body is increased from an ordinary temperature of 25° C. to a maximum temperature of 220° C. in 60 minutes, kept at 220° C. for 60 minutes, and then cooled to the ordinary temperature over 60 minutes. In this way, a wiring board is obtained.

### (Evaluation)

### <Resistance Value Test>

Resistance values of 100 via-hole conductors formed in the obtained wiring board are measured by a four-terminal method. Then, the initial resistance value and the maximum resistance value are obtained for each of the 100 via-hole conductors. In the initial resistance values, values of 2 mΩ or less are evaluated as “A” and values exceeding 2 mΩ are evaluated as “B.” Also, in the maximum resistance values, values of less than 3 mΩ are evaluated as “A”, and values of more than 3 mΩ are evaluated as “B.”

Herein, the initial resistance value (initial average resistance value) is calculated by forming a daisy chain including 100 vias, measuring the total resistance values of the 100 vias, and dividing the measured values by 100. Furthermore, the maximum resistance value is a maximum value among the average resistance values of 100 daisy chains each including 100 vias. Note here that Table 1 shows resistance values (mΩ) and specific resistance values (m·Ω).

### <Connection Reliability>

The wiring board whose initial resistance value has been measured is subjected to 500 cycles of heat cycle tests. The via-hole conductors having 10% or less of change rate with respect to the initial resistance value are evaluated as “A,” and those having more than 10% of change rate are evaluated as “B”.

The results are shown in Table 1. Furthermore, FIG. 10 shows a ternary diagram showing the respective compositions of Examples and Comparative Examples shown in Table 1. In Table 1 and FIG. 10, Examples 1 to 17 are represented by E1 to E17, and Comparative Examples 1 to 9 are represented by C1 to C9. In the ternary diagram of FIG. 10, each “white circle” denotes a composition of each of Examples, and a “black circle” denotes a composition of Comparative Example 1 (C1) in which a Bi amount relative to a Sn amount is smaller than in the metal compositions in Examples. Furthermore, a “white triangle” denotes a composition of Comparative Example 7 (C7) in which the Bi amount relative to the Sn amount is larger than in the metal compositions in Examples; each “white square” denotes a composition of each of Comparative Examples 2, 4, 6, and 9 (C2, C4, C6, and C9) in which the Sn amount relative to the Cu amount is larger than in the metal compositions in Examples; and each “black triangle” denotes a composition of each of Comparative Examples 3, 5, and 8 (C3, C5, and C8) in which the Sn amount relative to a Cu amount is smaller than in the metal compositions in Examples.

TABLE 1

| | Metal composition | | | | | | | | Evaluation | | | |
|---|---|---|---|---|---|---|---|---|---|---|---|---|
| | Weight | | | | Initial | Maximum | Initial | Maximum | Initial | Maximum | Connec- | Plot |
| Sam- | composition | solder | Cu | Solder | resistance | resistance | resistance × | resistance × | resis- | resis- | tion | in |
| ple | ratio | compo- | particle | amount | value | value | 10⁻⁷ | 10⁻⁷ | tance | tance | reli- | FIG. |
| No. | (Cu:Sn:Bi) | sition | (wt %) | (wt %) | (mΩ) | (mΩ) | (Ω · m) | (Ω · m) | value | value | ability | 10 |
| C1 | 0.59:0.3895:0.0205 | Sn—5Bi | 59 | 41 | 1.01 | 1.25 | 1.78 | 2.21 | A | A | B | |
| E1 | 0.57:0.387:0.043 | Sn—10Bi | 57 | 43 | 1.3 | 1.42 | 2.30 | 2.51 | A | A | A | ○ |
| E2 | 0.37:0.567:0.063 | Sn—10Bi | 37 | 63 | 1.8 | 1.99 | 3.18 | 3.52 | A | A | A | ○ |
| C2 | 0.33:0.603:0.067 | Sn—10Bi | 33 | 67 | 2.1 | 2.51 | 3.71 | 4.44 | B | A | A | □ |
| C3 | 0.93:0.0504:0.0196 | Sn—28Bi | 93 | 7 | 0.91 | 1.8 | 1.61 | 3.18 | A | A | B | ▴ |
| E3 | 0.87:0.0936:0.0364 | Sn—28Bi | 87 | 13 | 0.99 | 1.1 | 1.75 | 1.94 | A | A | A | ○ |
| E4 | 0.52:0.3456:0.1344 | Sn—28Bi | 52 | 48 | 1.5 | 1.8 | 2.65 | 3.18 | A | A | A | ○ |
| E5 | 0.32:0.4896:0.1904 | Sn—28Bi | 32 | 68 | 1.9 | 2.1 | 3.36 | 3.71 | A | A | A | ○ |
| C4 | 0.28:0.5184:0.2016 | Sn—28Bi | 28 | 72 | 2.2 | 2.5 | 3.89 | 4.42 | B | A | A | □ |
| C5 | 0.9:0.05:0.05 | Sn—50Bi | 90 | 10 | 0.92 | 1.3 | 1.63 | 2.30 | A | A | B | ▴ |
| E6 | 0.82:0.09:0.09 | Sn—50Bi | 82 | 18 | 0.94 | 1.1 | 1.66 | 1.94 | A | A | A | ○ |
| E7 | 0.43:0.285:0.285 | Sn—50Bi | 43 | 57 | 1.8 | 2.2 | 3.18 | 3.89 | A | A | A | ○ |
| E8 | 0.25:0.375:0.375 | Sn—50Bi | 25 | 75 | 2.0 | 2.8 | 3.53 | 4.95 | A | A | A | ○ |
| C6 | 0.21:0.395:0.395 | Sn—50Bi | 21 | 79 | 2.5 | 3.1 | 4.42 | 5.48 | B | B | A | □ |
| C7 | 0.73:0.081:0.189 | Sn—70Bi | 73 | 27 | 1.21 | 1.6 | 2.14 | 2.83 | A | A | B | Δ |
| C8 | 0.89:0.0462:0.0638 | Sn—58Bi | 89 | 11 | 0.94 | 1.28 | 1.66 | 2.26 | A | A | B | ▴ |
| E9 | 0.79:0.0882:0.1218 | Sn—58Bi | 79 | 21 | 1.19 | 1.59 | 2.10 | 2.81 | A | A | A | ○ |
| E10 | 0.60:0.168:0.232 | Sn—58Bi | 60 | 40 | 1.28 | 1.67 | 2.26 | 2.95 | A | A | A | ○ |
| E11 | 0.39:0.2562:0.3538 | Sn—58Bi | 39 | 61 | 1.8 | 2.1 | 3.18 | 3.71 | A | A | A | ○ |
| E12 | 0.22:0.3276:0.4524 | Sn—58Bi | 22 | 78 | 1.9 | 2.5 | 3.36 | 4.42 | A | A | A | ○ |
| C9 | 0.18:0.3444:0.4756 | Sn—58Bi | 18 | 82 | 2.1 | 3.1 | 3.71 | 5.48 | B | B | A | □ |
| E13 | 0.89:0.10:0.01 | Sn—10Bi | 89 | 11 | 0.95 | 1.2 | 1.68 | 2.12 | A | A | A | ○ |
| E14 | 0.733:0.240:0.027 | Sn—10Bi | 73 | 27 | 1.05 | 1.36 | 1.86 | 2.40 | A | A | A | ○ |
| E15 | 0.8:0.144:0.056 | Sn—28Bi | 80 | 20 | 1.15 | 1.45 | 2.03 | 2.56 | A | A | A | ○ |
| E16 | 0.7:0.216:0.084 | Sn—28Bi | 70 | 30 | 1.22 | 1.5 | 2.16 | 2.65 | A | A | A | ○ |
| E17 | 0.564:0.183:0.253 | Sn—58Bi | 56 | 44 | 1.34 | 1.72 | 2.37 | 3.04 | A | A | A | ○ |

From FIG. 10, it is shown that the compositions of Examples evaluated as “A” in evaluation of all of the initial resistance value, the maximum resistance value, and the connection reliability have a weight ratio (Cu:Sn:Bi) in a ternary diagram in a region surrounded by a quadrangle having apexes at points A (0.37:0.567:0.063), B (0.22:0.3276:0.4524), C (0.79:0.09:0.12), and D (0.89:0.10:0.01). Herein, the point A shows Example 2 (E2), the point B shows Example 12 (E12), the point C shows Example 9 (E9), and the point D shows Example 13 (E13).

Furthermore, a quadrangle having apexes at points C (0.79:0.09:0.12), D (0.89:0.10:0.01), E (0.733:0.240:0.027), and F (0.564:0.183:0.253) is evaluated as “A” in evaluation of all of the initial resistance value, the maximum resistance value, and the connection reliability. Herein, the point E shows Example 14 (E14), and the point F shows Example 17 (E17). In this way, the weight ratio (Cu:Sn:Bi) in the ternary diagram is made to be in the range surrounded by the quadrangle having apexes at points C (0.79:0.09:0.12), D (0.89:0.10:0.01), E (0.733:0.240:0.027), and F (0.564:0.183:0.253), and thereby the weight ratio of Cu having a lower resistance value is increased, so that low resistance of the via hole is achieved. Furthermore, all of Cu and Sn are subjected to an alloying reaction, and thereby Sn—Bi is not melted again. Thus, a printed wiring board having high reliability is achieved.

Furthermore, in a composition region of Comparative Example 7 (C7) which is plotted with the “white triangle” in FIG. 10 in which the Bi amount relative to the Sn amount is large, an amount of bismuth deposited in the via is increased. The volume resistivity of Bi is 78 μΩ·cm, which is remarkably larger as compared with volume resistivity of Cu (1.69 μΩ·cm), that of Sn (12.8 μΩ·cm), and that of compounds of Cu and Sn (Cu₃Sn: 17.5 μΩ·cm, and Cu₆Sn₅: 8.9 μΩ·cm). Therefore, when the volume resistivity of these metal materials is taken into account, as the Bi amount relative to the Sn amount is increased, the volume resistivity thereof is expected to be increased. Furthermore, it is likely that the resistance value varies depending on states in which bismuth is present or scattered, or the connection reliability is reduced.

Furthermore, in regions of Comparative Examples 2, 4, 6, and 9 (C2, C4, C6, and C9) each of which is plotted with the “white square” in FIG. 10 in which the Sn amount relative to the Cu amount is large, formation of the surface contact portion in copper particles by compression is insufficient. Furthermore, since a Sn—Cu compound layer is formed on the contact portion between copper particles after counter diffusion, an initial resistance value and a maximum resistance value are high values.

Furthermore, in the composition in a composition region of Comparative Example 1 (C1) which is plotted with the “black circle” in FIG. 10 in which the Bi amount relative to the Sn amount is small, since the Bi amount is small, the amount of solder melted at about 140° C. that is the eutectic temperature of the Sn—Bi solder particle is reduced. Consequently, the Sn—Cu compound layer for strengthening the surface contact portion between copper particles cannot be formed sufficiently, and thus, the connection reliability is reduced. That is to say, in Comparative Example 1 (C1) using Sn-5Bi solder particles, it is presumed that the initial resistance value and the maximum resistance value are low because a surface contact portion of copper particles is formed, but the solder particles are not easily melted because the Bi amount is small, so that the reaction between Cu and Sn forming a compound layer for strengthening the surface contact portion does not sufficiently proceed.

Furthermore, in a composition region of Comparative Examples 3, 5, and 8 (C3, C5, and C8) each of which is plotted with the “black triangle” in FIG. 10 in which the Sn amount relative to the Cu amount is smaller, since the Sn amount relative to the copper particles is small, a compound layer of Sn—Cu formed for strengthening the surface contact portion of copper particles is reduced, and therefore the connection reliability is reduced.

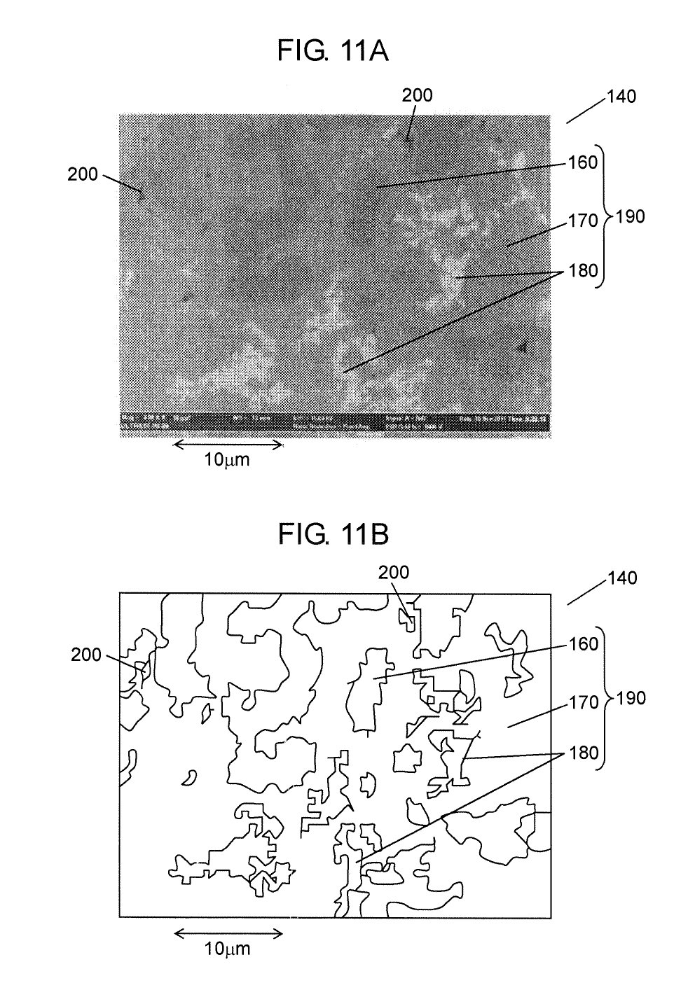

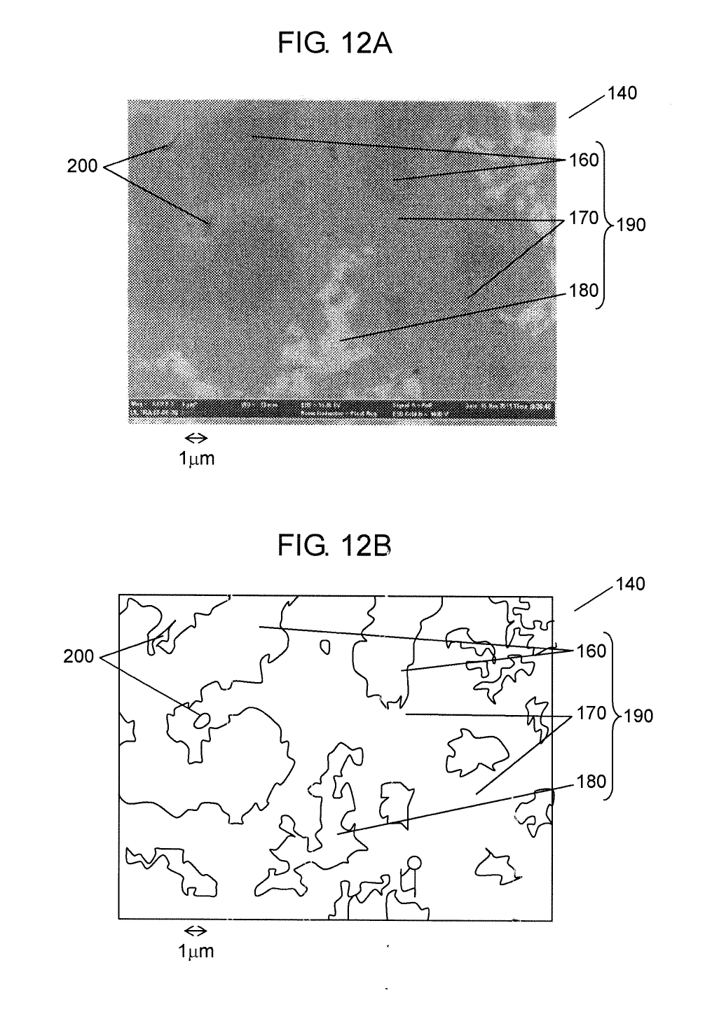

FIGS. 11A and 12A are scanning electron microscope (SEM) photographs each showing a cross-section of a via-hole conductor of a multilayer wiring board obtained by using paste (the weight ratio of copper particles Sn-28Bi solder is 70:30) in accordance with Example 16 (E16). FIGS. 11B and 12B are schematic views thereof, respectively. FIGS. 11A and 11B are shown at a magnification of 3000 times, and FIGS. 12A and 12B are shown at a magnification of 6000 times.

FIGS. 11A to 12B show that the via-hole conductor of the present exemplary embodiment has an extremely high filling rate of metal. Via-hole conductor 140 includes resin portion 200, and metal portion 190. Resin portion 200 includes epoxy resin. Metal portion 190 includes first metal region 160 mainly composed of copper, second metal region 170 mainly composed of a tin-copper alloy, and third metal region 180 mainly composed of bismuth. The size (furthermore, one or more of a volume, a weight, and a sectional area) of second metal region 170 is larger than those of first metal region 160, and those of third metal region 180. With this configuration, a plurality of wirings 120 are electrically coupled to each other by way of second metal region 170. Furthermore, first metal regions 160 and third metal regions 180 are scattered in a state in which they are not brought into contact with each other in second metal region 170, and thereby an alloying reaction (furthermore, a formation reaction of an intermetallic compound) can be carried out uniformly without variations.

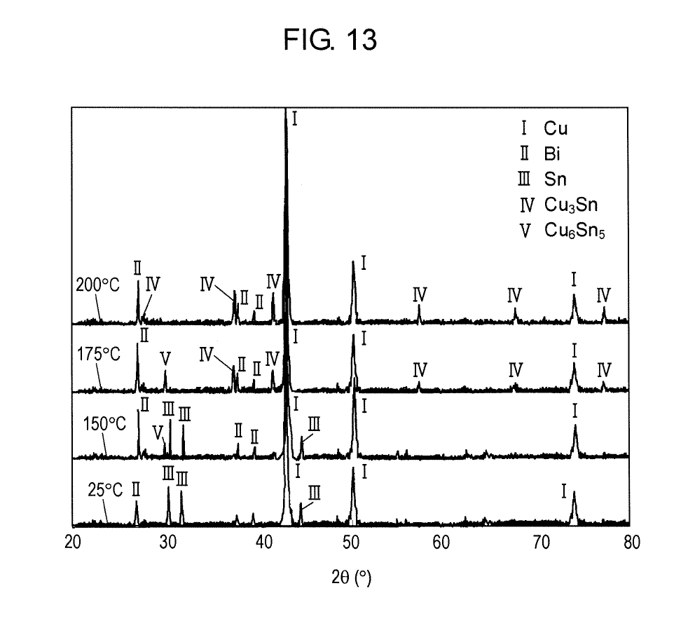

FIG. 13 is a graph showing one example of analysis results by X-ray diffraction (XRD) of the via-hole conductor. Peak I is a peak of Cu (cupper). Peak II is a peak of Bi (bismuth). Peak III is a peak of tin (Sn). Peak IV is a peak of an intermetallic compound Cu₃Sn. Peak V is a peak of an intermetallic compound Cu₆Sn₅.

FIG. 13 evaluates an effect of heating temperatures (curing temperatures) at the time of pressurization on the via-hole conductors, and shows measurement results at the time when the heating temperature is 25° C., 150° C., 175° C., and 200° C., respectively. In FIG. 13, X-axis is 20 (unit is)° and Y-axis is strength (unit is arbitrary).

Note here that samples used for measurement are pellets made of via paste and having different treatment temperatures. For the X-ray diffraction, “RINT-2000” manufactured by Rigaku Corporation is used.

From the graph of the X-ray diffraction shown in FIG. 13, when the temperature is 25° C., peak I of Cu, peak II of Bi, and peak III of Sn are detected, but peak IV of Cu₃Sn and peak V of Cu₆Sn₅ are not detected.

When the temperature is 150° C., peak V of Cu₆Sn₅ appears, although it is only slight, in addition to peak I of Cu, peak II of Bi, and peak III of Sn.

When the temperature is 175° C., peak IV of Cu₃Sn appears in addition to peak I of Cu, peak II of Bi, and peak V of Cu₆Sn₅. Peak III of Sn almost disappears. From the above mention, it is shown that an alloying reaction between Cu particles and Sn—Bi solder particles, and furthermore, a formation reaction of an intermetallic compound uniformly proceed.

In the graph of FIG. 13 in which a sample temperature is 200° C., peak I of Cu, peak II of Bi, and peak IV of Cu₃Sn are detected, but peak III of Sn and peak V of Cu₆Sn₅ disappear. From the above mention, it is shown that an alloying reaction between Cu particles and Sn—Bi solder particles, and furthermore, a formation reaction of an intermetallic compound proceed, and that the alloying reaction between Cu particles and Sn—Bi solder particles and furthermore the formation reaction of an intermetallic compound are stabilized by generation the peak IV of Cu₃Sn.

As mentioned above, in the present exemplary embodiment, the intermetallic compound is not Cu₆Sn₅ but Cu₃Sn that is more stable, and thereby the reliability of the via-hole conductor is enhanced. In other words, in the present exemplary embodiment, it is possible to carry out an alloying reaction (or a formation reaction of an intermetallic compound) in which an intermetallic compound is Cu₃Sn that is more stable than Cu₆Sn₅.

Note here that the thickness of the heat-resistant film that is incompressible member 220 is desirably 3 μm or more and 55 μm or less, further desirably, 50 μm or less and yet further desirably 35 μm or less. When the thickness of the heat-resistant film is less than 3 μm, the film strength is deteriorated, and a compression effect of via paste 260 may not be obtained. Since a heat-resistant film having a thickness of more than 55 μm is specific and expensive, a heat-resistant film having a thickness of 55 μm or less is preferably used.

Furthermore, the thickness per one side of thermosetting adhesive layer 210 provided on the surface of incompressible member 220 is desirably 1 μm or more and 15 μm or less. When the thickness is less than 1 μm, predetermined adhesion strength may not be obtained. Furthermore, when the thickness is more than 15 μm, a compression effect of via paste 260 may not be obtained. Note here that it is useful that the thickness of incompressible member 220 is larger than the thickness of one side of thermosetting adhesive layer 210.

When the thickness of incompressible member 220 is 75 μm, the volume fraction of metal portion 190 in via-hole conductor 140 may be able to be increased only to about 60 vol % or more and 70 vol % or less.

For example, when the thickness of incompressible member 220 is 50 μm (when 10 μm-thick thermosetting adhesive layer 210 is formed on each of both surfaces thereof, the thickness of electric insulating base material 130 is 70 μm), the volume fraction of metal portion 190 in via-hole conductor 140 is 80 vol % or more and 82 vol % or less.

When the thickness of incompressible member 220 is 40 μm (when 10 μm-thick thermosetting adhesive layer 210 is formed on each of both surfaces thereof, the thickness of electric insulating base material 130 is 60 μm), the volume fraction of metal portion 190 in via-hole conductor 140 becomes 83 vol % or more and 85 vol % or less.

When the thickness of incompressible member 220 is 30 μm (when 10 μm-thick thermosetting adhesive layer 210 is formed on each of both surfaces thereof, the thickness of electric insulating base material 130 is 50 μm), the volume fraction of metal portion 190 in via-hole conductor 140 becomes 89 vol % or more and 91 vol % or less.

When the thickness of incompressible member 220 is 20 μm (when 10 μm-thick thermosetting adhesive layer 210 is formed on each of both surfaces thereof, the thickness of electric insulating base material 130 is 40 μm), the volume fraction of metal portion 190 in via-hole conductor 140 becomes 87 vol % or more and 95 vol % or less.

When the thickness of incompressible member 220 is 10 μm (when 10 μm-thick thermosetting adhesive layer 210 is formed on each of both surfaces thereof, the thickness of electric insulating base material 130 is 30 μm), the volume fraction of metal portion 190 in via-hole conductor 140 becomes 98 vol % or more and 99.5 vol % or less.

As mentioned above, the smaller the thickness of incompressible member 220 is, the higher the effect is. However, the thickness is appropriately selected according to the diameter, density, and application of use, or the like, of via-hole conductor 140.

From the above mention, it is shown that when incompressible member 220 is used, the volume fraction of metal portion 190 in via-hole conductor 140 is increased.

### INDUSTRIAL APPLICABILITY

A wiring board in accordance with the present exemplary embodiment has effects in reducing a cost, reducing a size, improving performance, and enhancing reliability, and therefore it is used for portable telephones or the like.

### REFERENCE MARKS IN THE DRAWINGS

110, 111 multilayer wiring board
120, 120a, 120b, 121a, 121b wiring
130 electric insulating base material
140 via-hole conductor
150 metal foil
160 first metal region
170 second metal region
180 third metal region
190 metal portion
200 resin portion
210 thermosetting adhesive layer
220 incompressible member
230 uncured base material
240 protective film
250 through-hole
260 via paste
270 protruding portion
280, 280a, 280b, 280c, 280d arrow
290 copper particle
300 solder particle
310 thermosetting resin component
320 core material
330 semi-cured resin
340 compressible member
500 substrate
600 wiring board

1. A wiring board comprising:
an electric insulating base material including an incompressible member and a thermosetting member;
a first wiring and a second wiring formed with the electric insulating base material interposed therebetween; and
a via-hole conductor penetrating the electric insulating base material, and electrically connecting the first wiring and the second wiring to each other,
wherein the via-hole conductor includes a resin portion and a metal portion, and
the metal portion includes:
a first metal region mainly composed of Cu;
a second metal region mainly composed of a Sn—Cu alloy; and
a third metal region mainly composed of Bi, and
the second metal region is larger than the first metal region, and larger than the third metal region.

2. The wiring board of claim 1,
wherein the second metal region covers the first metal region and the third metal region.

3. The wiring board of claim 1,
wherein the first metal region and the third metal region are present in a state in which they are not brought into contact with each other.

4. The wiring board of claim 1,
wherein the second metal region includes Cu₆Sn₅ and Cu₃Sn, and a ratio of Cu₆Sn₅/Cu₃Sn is 0.001 or more and 0.100 or less.

5. The wiring board of claim 1,
wherein Cu:Sn:Bi that is a weight composition ratio of Cu, Sn and Bi in the metal portion is in a region surrounded by a quadrangle having apexes A (0.37:0.567:0.063), B (0.22:0.3276:0.4524), C (0.79:0.09:0.12), and D (0.89:0.10:0.01) in a ternary diagram.

6. The wiring board of claim 1,
wherein the metal portion in the via-hole conductor is 74.0 vol % or more and 99.5 vol % or less.

7. The wiring board of claim 1,
wherein the resin portion in the via-hole conductor is 0.5 vol % or more and 26.0 vol % or less.

8. The wiring board of claim 1,
wherein a weight ratio of a total of the first metal region and the second metal region to the via-hole conductor as a whole is 20% or more and 90% or less.

9. The wiring board of claim 1,
wherein the resin portion includes a cured product of epoxy resin.

10. The wiring board of claim 1,
wherein specific resistance of the via-hole conductor is 1.00×10⁻⁷ Ω·m or more and 5.00×10⁻⁷ Ω·m or less.

11. The wiring board of claim 1,
wherein the incompressible member is a film free from space inside thereof.

12. The wiring board of claim 1,
wherein a thickness of the incompressible member is 3 μm or more and 55 μm or less.

13. The wiring board of claim 1,
wherein the thermosetting member is epoxy resin.

14. The wiring board of claim 1,
wherein a thickness of the thermosetting member is 1 μm or more and 15 μm or less.

15. A method for manufacturing a wiring board, the method comprising:
providing protective films on both sides of a base material including an incompressible member and an uncured thermosetting member;
forming through-holes by perforating the base material covered with the protective films from an outer side of the protective films;
filling the through-holes with via paste including a copper particle, a solder particle containing tin and bismuth, and resin;
peeling off the protective films so as to form protruding portions each of which is formed of the via paste partially protruding from each of the through-holes;
disposing metal foil on a surface of the base material so as to cover the protruding portions;
applying pressure to the via paste from the metal foil for allowing a part of the resin to flow into the base material;
heating the via paste to cure the resin so as to form a via hole conductor which includes a resin portion and a metal portion,
the metal portion including:
a first metal region mainly composed of Cu;
a second metal region mainly composed of a Sn—Cu alloy, and
a third metal region mainly composed of Bi; and
the second metal region being larger than the first metal region, and larger than the third metal region; and
heating the base material to cure the thermosetting member; as well as
forming a wiring by patterning the metal foil.

16. The method for manufacturing a wiring board of claim 15,
wherein the incompressible member is free from space inside thereof.

17. The method for manufacturing a wiring board of claim 15,
wherein a thickness of the incompressible member is 3 μm or more and 55 μm or less.

18. The method for manufacturing a wiring board of claim 15,
wherein the thermosetting member is epoxy resin.

19. The method for manufacturing a wiring board of claim 15,
wherein a thickness of the thermosetting member is 1 μm or more and 15 μm or less.
